(19) United States
(12) Patent Application Publication
(10) Pub. No.: US 2004/0245583 A1
(43) Pub. Date: Dec. 9, 2004

(54) Semiconductor device and manufacturing method thereof

(76) Inventors: Masatada Horiuchi, Koganei (JP); Akio Shima, Hino (JP); Takashi Takahama, Higashimurayama (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/790,765

(22) Filed: Mar. 3, 2004

(30) Foreign Application Priority Data
Jun. 5, 2003 (JP) P2003-160431

(51) Int. Cl. H01L 29/80

(52) U.S. Cl. 257/408

(57) ABSTRACT

Source and drain diffusion layers by an extremely shallower box shaped highly doped impurity distribution that was not obtainable so far by the existent solid phase growing is attained by liquid phase growing with no effects on the gate electrode thereby attaining low consumption power and operation at large current and higher speed in a micro-refined semiconductor device. Contact with inter-connection layer over the entire region of the source and drain diffusion layers is enabled overstriding the gate electrode and without short circuit with the gate electrode by utilizing that the etching selectivity of an insulation film comprising Al as a main constituent atom is extremely higher with respect to an Si oxide film. Further, a metal film of a shallower decaying depth is disposed selectively only to the contact region thereby selectively heating Si indirectly locally by a laser light having a wavelength with deep decaying depth to Si and, accordingly, less heating the Si itself to liquefy only the ion implanted amorphous region of the diffusion layer to enable formation of source and drain junction in an extremely shallower box shaped highly doped impurity distribution.

### BACKGROUND OF THE INVENTION

1. Field of the Invention

The present invention concerns a semiconductor device and a manufacturing method thereof and, it particularly relates to the improvement for the performance and the micro-refinement of transistors by lowering resistance, extremely shallowing junction and micro-refinement of a diffusion layer of a gate insulated field effect transistor disposed on a single crystal semiconductor substrate or a semiconductor thin film on an insulation film.

2. Description of the Related Art

The prior art relevant to the invention includes a contact forming technique for the source and drain diffusion layers of an insulated gate field effect transistor (hereinafter referred to as IGFET) and, particularly, a technology regarding the formation of self alignment contact to a gate electrode. The self alignment contact technique enabling electrode connection from the end of the gate electrode to the source and drain diffusion layers in a state of maintaining a predetermined distance is known. This is a technique of selecting an optimum material for a gate electrode side insulation film in the etching of an inter-connection insulation film material thereby providing protection also against mask misalignment in which a contact hole region overlaps with a gate electrode by the gate electrode side wall insulation film and not causing short circuit between the gate electrode and the source and the drain electrodes.

In the formation of the existent self alignment contact, a silicon nitride film was used as the gate side wall insulation film and a silicon oxide film was used as the inter-connection insulation film to be formed with a contact hole. However, since the difference of the etching rate between both of them is only 5 to 6 times at the greatest and since scraping of the silicon nitride film is not negligible in the IGFET structure in which the gate side wall insulation film has no sufficient thickness, short circuit with the gate electrode could not be eliminated.

Further, another prior art relevant to the invention includes shallowing of junction for the source and drain diffusion layers along with refinement and higher integration degree of IGFET. The demand for the shallower junction of the source and drain diffusion layers is strict and attainment of lower resistance for an extremely shallower junction at about 10 nm of the junction depth for practical use of micro-refined IGFET with the gate length of 30 nm or less. The values for the gate length and the junction depth can not be attained by the existent ion implantation and the subsequent short time high temperature anneal for about one sec since diffusion of impurities is not negligible. As a further shorter time anneal, it has been required to make the anneal practical, for example, by laser light irradiation having a pulse width of about several tens nano sec. In the laser light irradiation, since the irradiation energy absorption depth can be restricted to an extreme surface region, heating at super-high temperature for extremely shortened time is possible such as by melting only the source and drain surface regions selectively and suppressing the thermal diffusion to the underlying single crystal region to the minimum level.

Accordingly, since the solid solubility of impurities at high concentration constituting the source and drain diffusion layers can also be increased outstandingly in a molten state, lowering of resistance can also be expected irrespective of the extremely shallower junction. Further, since the diffusion rate of impurities in the molten state is higher by 8 digits or more compared with the solid phase diffusion, it is theoretically possible to make the source and drain junction as an extremely shallower junction with a box shaped impurity doping distribution which enables reduction of punch-through leak current and further micro-refinement and, accordingly, high integration degree of IGFET.

The anneal method using the laser light irradiation is known and proposed, for example, as an activating annealing for shallower junction source and drain diffusion layers in a micro-refined IGFET as shown in the cross sectional view of FIG. 2. In FIG. 2, highly doped impurity implantation regions 5 and 52 are constituted in the main surface region of a single crystal silicon (Si) substrate 1 by an ion implantation method using a gate electrode 4 formed by way of a thin gate insulation film 3 on the single crystal Si substrate 1 as an implantation inhibitive mask. By heating or selectively melting the highly doped impurity implantation regions 5 and 52 by laser light irradiation from the side of the main surface by way of a protection insulation film 65, single crystallization and activation of implanted impurities are conducted. Since the laser light irradiation region is much wider as compared with the transistor region, the laser light is irradiated inevitably to the portion of the gate electrode 4, and the gate electrode 4 usually constituted with the polycrystalline silicon film is also annealed. The gate electrode 4 extends also on the inter-device isolation insulation film and the heat absorbed in the gate electrode is less released to the underlying substance because of the inter-device isolation insulation film in a state where the polycrystalline silicon film is melted locally to cause a problem of failure such as melting, evaporation or loss of pattern. In the known example shown in FIG. 2 (for example, refer to Japanese Patent Laid-Open No. H6(1994)-5536), a gate protection insulation film 44 having an identical optical constant with that of the protection insulation film 65 is superposed in order to selectively decrease the intensity of the laser light reaching the gate electrode 4. Usually, a gas laser such as an Xe—Cl laser having a wavelength of 308 nm or a Kr—F laser having a wavelength of 248 nm is used for the activation and single crystallization of the highly doped impurity implantation layer in the main surface region of the Si substrate 1. Generally, the decay depth of light, i.e., a depth Ã at which the relative light intensity reaches e⁻² is represented as Ã=λ/2πk, where λ represents a wavelength of the laser light and k represents an imaginary value for the optical constant of the substance k of amorphous Si at a wavelength of 308 nm is about 3.06. Accordingly, Ã is as shallow as 16 nm and since penetration to a deep portion is negligible, only the surface of the Si substrate 1 is annealed and melted depending on the energy intensity. While the laser light is irradiated pulsatively, since it is usually as short as about several tens ns, the molten region is instantaneously crystallized into a solid phase and heat diffusion to the deeper portion is negligible. In a case where the protection insulation film 65 and the gate protection insulation film 44 above the Si substrate are constituted with a silicon oxide film, the reflectivity has a film thickness dependence and in the laser light of the wavelength described above, the reflectivity is 0.6 at a film thickness of 0 and near 105 nm and takes a minimum value of about 0.3 near 45 nm. That is, the thickness of the protection insulation film 65 is 45 nm above the highly doped impurity implantation regions 5 and 52 requiring the activation treatment and the total film thickness for the gate protection insulation film 44 and the protection insulation film 65 is 105 nm above the gate electrode 4 where the laser light irradiation energy is intended to be lowered. Thus, the reflectivity can be increased relatively on the gate electrode 4, and temperature elevation at the gate electrode can be decreased to some extent. However, when the end of the gate electrode 4 is noted in the deposited film constitution comprising the gate protection insulation film 44 and the protection insulation film 65 shown above, the thickness of the protection insulation film 65 in the vertical direction depends on the height of the gate and the intensity of the laser energy absorbed in the ion implanted amorphous layer just below the gate electrode end is lowered compared with other regions of a planer substrate. Since the laser heat treatment method has not been popularized so far, the dependency on the underlying shape has not yet been considered so far.

### SUMMARY OF THE INVENTION

A first subject of the present invention concerns extension of source and drain electrodes, and enabling so-called self-alignment contact formed in a self-alignment relation with the gate electrode also for a thin gate electrode side wall insulation film thereby making it possible for micro-refinement and higher integration of a semiconductor device. Particularly, it intends to provide a method of applying a self-alignment contact structure even under a situation where the height of the gate electrode is also decreased along with micro-refinement of the gate electrode.

A second subject of the invention is to overcome the dependence of the laser light intensity on the shape of an object to be irradiated in the laser light irradiation. A heat treatment effect equal with that for the diffusion layer in the planar region has to be ensured also for source and drain diffusion portions just below the gate electrode end. A further problem concerning the effect of underlying shape is serious in a semiconductor device constituting, for example, a logic circuit referred to as a NAND gate. In the NAND gate, gate electrodes are usually disposed each at a minimum line distance by the number of input signals based on the manufacturing technique, in which the vertical thickness of the deposition film is increased more also on the diffusion layer region between the gate electrodes disposed each at the minimum line distance than that on other planar regions by the sum for the height of the gate electrode 4 and the thickness of the gate protection of insulation film 44, to result in a problem that it deviates from the optimum optical film thickness regarding the laser light absorption.

Description is to be made for the example of FIG. 2. In the figure in a case of forming, the protection insulation film 65 at 45 nm thickness the vertical thickness on the side wall of the gate electrode 4 is determined by the sum for the height of the gate electrode 4 and the gate protection insulation film 44 and it can not be 45 nm thickness. Accordingly, the relative intensity of the attainable laser light irradiation is decayed depending on the height of the gate electrode 4 on the surface of the semiconductor substrate at the end of the gate electrode 4 by so much as the distance for the film thickness of 45 nm of the protection insulation film 65. That is, this results in a problem of decreasing the relative intensity of the laser light irradiation to the important source and drain junction end region adjacent with the gate electrode 4 in which a substitution means by the additional constitution of a deeper diffusion region or metal silicidation for the serial source resistance of the transistor, that is, a determinative factor restricting the increase of current. While complete crystallization free from crystal defects is attained in the molten and re-crystallized diffusion layer at a sufficient irradiation energy intensity, activation of the diffusion layer is insufficient at an insufficient irradiation energy intensity in which lowering of the resistance can not be attained, to result in leaving of crystal defects and twins in the diffusion layer. Accordingly, even under the activating anneal condition by the laser light irradiation intensity optimal to the activation of the diffusion layer in the region sufficiently spaced from the end of the gate electrode, only the structure of high resistance with remaining twins can be obtained and improvement in the performance as the semiconductor device can not be attained substantially.

However, the foregoing problems were not taken into consideration until the limit of the existent short time high temperature anneal method and the practical use of the laser anneal method were brought up to topics in the manufacture of the micro-refined IGFET. That is, the problems described above have been newly found along with micro-refinement of the IGFET. The present invention intends to provide a method of optimally setting the intensity of the laser light irradiation or additional anneal temperature not depending on the shape of an object to be irradiated with laser light, for example, the height of the gate electrode, and provide a method of capable of large current operation and less current leakage in a micro-refined insulated gate field effect transistor or the like.

Another subject of the invention is to overcome a problem inherent to laser irradiation apparatus used usually in activation or crystallization of semiconductor devices or thin film transistors, that is, a problem that a light at ultra-short wavelength, for example, of 308 nm or 248 nm can not be generated with those other than rare gas lasers such as Xe—Cl or Kr—F, the gas laser apparatus are expensive in the apparatus per se, as well as that they involve a problem in view of the stability and the reproducibility of output waveform and that they require maintenance cost of 40,000,000 yen/year or more only for always attaining stable operation while taking the degradation of the output waveform into consideration. Use of solid lasers such as YAG laser is desirable at present with a view point of stable operation and saving of the maintenance cost (the subject will be solved if the performance of the gas laser can be improved in the feature). However, even when YAG laser (wavelength at 1064 nm) is irradiated to a semiconductor device as shown in FIG. 2, the Ã value is several μm, which is much deeper than the active region depth of the micro-refined insulated gate field effect transistor or the thin film transistor manufactured with a semiconductor thin film of about 50 nm thickness, and it can not be applied to the selective anneal for a desired depth region. Other subject of the invention is to enable localized selective anneal for a micro-refined semiconductor device or a thin film transistor by a laser light irradiation apparatus which is less expensive and capable of stable operation and attain improved performance of the micro-refined semiconductor device or thin film transistor at good yield.

A third subject of the invention is to basically overcome the fatal defect caused in a case of increasing the irradiated laser energy so as to sufficiently activate the source and drain junction region at the gate electrode end, that is, lowering of the yield for good products caused by configurational deformation or partial defects of the gate electrode. Since the basic concept of the existent laser irradiation anneal utilizes the phenomenon that the light at an ultra-short wavelength such as of 248 nm or 308 nm is absorbed to cause heating at the extreme surface region of silicon or like other semiconductor substrate, the gate electrode constituted with the semiconductor material, such as silicon was also inevitably self-heated. That is, when the irradiation laser energy increases, heat generation in the gate electrode per se is inevitable even if the reflectivity on the gate electrode is somewhat decreased, and laser energy conditions capable of sufficiently activating the source and drain junction region at the end of the gate electrode without causing fatal defects to the gate electrode were scarcely present when taking the pattern dependence of the integrated circuits to be applied, and dependence on the dissipating conditions of the underlying part such as the gate electrode above the device isolation insulation film also into consideration. The invention intends to provide a method capable of basically overcoming the situation in the existent laser light irradiation anneal in that it can not substantially get out of the problem of self-heating of the gate electrode and no practical irradiation anneal conditions can be found dissolving the occurrence of fatal defects to the gate electrode or the like, thereby outstandingly improving the yield of good products by the laser light irradiation anneal, and activating the surface region of the source and drain junction including the gate electrode end selectively and sufficiently.

For solving the first subject, in the invention, an insulation film comprising Al as the main constituent atom such as an aluminum oxide film or an aluminum nitride film having a dry etching rate lower by 20 times or more compared with that of the silicon oxide film and comprising an insulation film is previously deposited below a silicon oxide film used as an inter-connection insulation film to be formed with a contact hole. The insulation film comprising Al as the main constituent atom may have a layered structure with a silicon oxide film or a silicon nitride film. Since the insulation film comprising Al as the main constituent atom is deposited so as to cover the entire portion above the gate electrode, the gate side wall insulation film and, further, the source and drain diffusion layer, the gate electrode and the gate side wall region are protected by the insulation film comprising Al as the main constituent atom even when opening for source and drain connection applied to the silicon oxide film is conducted by using a mask to extend for the entire active region including the gate electrode. Only the surface of the source and drain diffusion layers can be removed by selectively removing the insulation film comprising Al as the main constituent atom exposed in the step of opening the inter-connection insulation film comprising the silicon oxide film by using an aqueous solution of hydrogen fluoride or a solution of phosphoric acid. Since the dry etching selectivity can be increased more compared with that in the prior art using the silicon nitride film as the gate sidewall insulation film, failure such as short circuit between the source and drain connection electrode and the gate electrodes caused by scraping of the gate side wall insulation film can be improved outstandingly. Further, the insulation film comprising Al as the main constituent atom formed below the inter-connection insulation film can be exerted extremely effectively also for the lowering of the resistance of the extremely shallower junction source and drain diffusion layers as will be described later.

For solving the second subject described above, a solid laser device capable of obtaining stable output with outstandingly less fluctuation also including the aging change in the output waveform and requiring less maintenance cost compared with the gas laser device is used in the invention. In a case of using the solid laser device, an ultra short wavelength laser light obtained by the gas laser such as an XeCl laser (308 nm wavelength) or KrF laser (248 nm wavelength) can not be obtained. The short wavelength laser obtained by the solid laser device put to practical use is, for example, YAG laser having a wavelength of 1064 nm. The laser light at the wavelength described above has a penetration depth Ã to Si as deep as several μm and can not directly heat an object in which the region to be annealed is restricted to an extremely shallow region of 50 nm or less. Accordingly, for enabling selective anneal to the extremely shallow region in the micro-refined semiconductor device by using a solid laser device such as a semiconductor-excited YAG laser, a method of disposing a laser energy absorbing film capable of sufficiently absorbing the laser light energy at the wavelength of the irradiation light to the surface of the object to be irradiated and heating the extremely shallow region near the surface of the irradiated object indirectly by the laser light annealing of the laser energy absorbing film is adopted in this invention. In the invention, a high melting metal film of a single layered or multi-layered structure is used for efficiently absorbing the laser light at the wavelength of 1064 nm and lowering the heat resistance in the absorbing film per se, an Si film or a mixed Ge and Si film is further used as an anti-reflective film on the laser energy absorbing film. For preventing reaction between the irradiated object and the laser energy absorbing film, a surface protection film such as an insulation film is preferably inserted. For the surface protection film, use of a material of an extremely thin film thickness, excellent in heat conductivity and excellent also in reaction preventive property is preferred in order to transfer the heat generated in the laser energy absorbing film rapidly and with no loss. In a case where the irradiated object is the surface of a semiconductor substrate such as made of Si, an alumina film or a silicon nitride film is preferred specifically. The film thickness is preferably 20 nm or less and about 10 nm in view of the controllability. For the laser energy absorbing film, it is essential that the film is excellent in the heat conductivity and stable also at high temperature of about 1400° C. Specifically, a high melting metal film such as made of Ti, W, Ta or Mo and a single layered nitride film or silicide film of the high melting metal described above, or a layered film thereof is preferred. Further, for preventing reaction with the anti-reflective film layered on the laser energy absorbing film, it is preferred that a material film, for example, a TiN film which is stable and having low heat resistivity to the uppermost layer of the laser energy absorbing film in order to prevent reaction with the anti-reflective film layered on the laser energy absorbing film.

The energy absorbing property of the YAG laser light at the wavelength of 1064 Nm in the high melting metal film is a function of the film thickness of the anti-reflective film and, in a case of the Si anti-reflective film, the reflectivity can be substantially zero and the energy absorptivity can be about 90% at the film thickness of 50 nm and 200 nm. The reflectivity is maximized at a thickness of 130 nm of the Si anti-reflective film. With the film constitution layered as described above, the temperature near the surface of the underlying portion can be elevated to 1400° C. or higher based on the setting conditions for the irradiation laser light energy of several tens n sec, which is substantially equal with the pulse width of the irradiated laser. Accordingly, in a case where the underlying layer is Si, melting and subsequent recrystallization are possible in the surface layer region. Amorphous portion constituted on single crystals or polycrystals starts crystal growing at a relatively low temperature depending on the crystal orientation of the underlying portion. Accordingly, formation of the laser energy absorbing film or the anti-reflective film has to be conducted at a sufficiently low temperature so that no recrystallization is caused substantially in the amorphous region before the irradiation of the laser light. In order not to substantially re-crystallize the amorphous region of about 10 nm thickness on the single crystal Si, all film deposition steps have to be conducted at 450° C. or lower. Based on the method described above, the region to be heated can be annealed in an extremely short time and at an extremely high temperature by using a solid laser device of stable output property and with less maintenance cost.

For solving the third subject described above of preventing over-heating to the gate electrode extended on the inter-device isolation insulation film, opening is applied to the inter-connection insulation film at an active region portion of IGFET including the gate electrode, and the laser energy absorbing film is left selectively only in the opened region in the invention. The problem regarding the scraping of the gate electrode side wall insulation film in the opening for the silicon oxide film can be solved by disposing at least a thin insulation film comprising Al as a main constituent atom below the inter-connection insulation film for the opening. Further, the thin insulation film comprising Al as the main constituent atom is used both as a surface protection film for preventing reaction between the laser energy absorbing film comprising a metal film and the Si substrate in the laser irradiation step. For example, in a case of an alumina film, the heat conductivity is substantially 1/10 of the silicon oxide film and the heat conduction efficiency to the source and drain junction region to be heated can be improved. As a method of selectively leaving the laser energy absorbing film to the opening in the inter-connection insulation film, the surface of the inter-connection insulation film is at first planarized, for example, by chemical mechanical polishing and the laser energy absorbing film is deposited for the entire surface to completely fill the opened region and leave the film selectively only to the opened region by the chemical mechanical polishing as far as the inter-connection insulation film surface as an end point. Then, the anti-reactive film and the anti-reflective film may be deposited successively from the state on the planarized main surface. When the laser energy absorbing film is left above the gate electrode, the gate electrode itself is also heated. In order to prevent heating for the gate electrode, when the thickness of the inter-connection insulation film and the effective height of the gate electrode are designed such that they are substantially identical, the surface of the gate electrode and the surface of the inter-connection insulation film are aligned by the chemical mechanical polishing step and the laser energy absorbing film is not left on the gate electrode, so that direct heating to the gate electrode can be avoided. In order to suppress heating of the gate electrode from the side wall, the treatment may be conducted based on the method described above after previously forming the gate side wall insulation film to the gate electrode. It may suffice that the thickness of the gate sidewall insulation film is sufficiently thick compared with that of the surface protection film and the heat conduction is suppressed sufficiently.

According to the method described above, fluctuation of the thickness for the laser energy absorbing film or the anti-reflective film depending on the unevenness in the underlying portion can be minimized and the thickness of the layered film can be designed to an optically optimized thickness in the entire region to be heated. A silicon oxide film or a silicon nitride film can be used as a less polishing material for the polishing of the laser energy absorbing film or the anti-reflective film. Based on the chemical mechanical polishing method customarily used in the method of manufacturing semiconductor devices, the polishing ratio between the laser energy absorbing film comprising the high melting metal film and the anti-reflective film comprising Si and the less polishing film such as a silicon oxide film or a silicon nitride film reaches as high as 30 times or more and selective polishing can be attained satisfactorily.

In the invention, the laser light irradiation anneal is applied in the stage after completing the first ion implantation step for forming an extremely shallower source and drain junction using the gate electrode as an implantation inhibitive mask and the subsequent second ion implantation step for forming a relatively deeper source and drain junction using the gate side wall insulation film as an implantation inhibitive mask in the existent method of manufacturing semiconductor devices. When the pulse laser irradiation condition is set to about several tens n sec so as to melt only the amorphous layer region in the source and drain junction and minimize heat conduction to the single crystal region, inside of the source and drain junction can be activated satisfactorily while preventing over heating of the gate electrode. Further, since source and drain diffusion layers having different junction depth can be activated collectively in this method, the junction impurity distribution in an ideal form can be maintained easily.

In a micro-refined complementary IGFET with the gate insulation film of about 2 nm or less, particularly, in a p-conduction type IGFET, a new problem occurs in addition to the problem of the deformation of the gate electrode by heating. That is, impurities at high concentrations added to the gate electrode readily leak and diffuse to the substrate also at a usual anneal temperature to cause failures such as fluctuation and scattering of threshold voltage. Accordingly, in preventing over heating of the gate electrode, it is necessary to dissolve not only the problem of the pattern deformation caused by existent laser irradiation but also dissolve an additional problem such as leakage and diffusion of impurities at high concentration added to the gate electrode or degradation of the gate insulation film. The method described above capable of sufficiently suppressing heat conduction from the upper portion and the side of the gate electrode can provide a sufficient range of manufacturing conditions also with regard to the new problem for the micro-refined complementary IGFET described above. According to the invention, over heating for the gate electrode and the non-activated region can be dissolved in a self-alignment manner with reference to the active region. Various problems relevant to the over heating can be dissolved irrespective of the presence or absence of the inter-device isolation insulation film which is poor in the heat conductivity and, accordingly, liable to undergo overheating just below the gate electrode.

The anneal according to the invention described above means that only the desired region in the semiconductor substrate can be applied with the anneal selectively. Accordingly, in a so-called BICMOS in which a complementary IGFET and a bipolar transistor are present together in one identical semiconductor substrate, only the source and drain regions of the complementary IGFET can be activated selectively with no effective anneal to the bipolar transistor. As another application use, activation for the emitter diffusion layer and the source and drain regions of the IGFET can be attained simultaneously while decreasing the thermal budget to the base diffusion layer of the bipolar transistor. The effects of the anneal hysteresis in the manufacture of the IGFET and the bipolar transistor respectively can not be eliminated so long as based on the existent manufacturing method for the BICMOS and high performance bipolar transistor and high performance IGFET can not be compatibilized with each other. However, with the constitution described above, the invention can overcome such existent disadvantage and can conduct heat treatment under the optimal condition for the bipolar transistor and the optimal condition for IGFET independently of each other. That is, according to the invention, a high performance bipolar transistors and a high performance IGFET can be constituted in one identical substrate.

### BRIEF DESCRIPTION OF THE DRAWINGS

FIG. 1 is a cross sectional view showing a manufacturing step of a semiconductor device according to a first embodiment of the present invention;

FIG. 2 is a cross sectional view showing an existent laser heat treatment step for a transistor;

FIG. 3 is a cross sectional view showing the order of a manufacturing step for a semiconductor device according to the first embodiment of the invention;

FIG. 4 is a cross sectional view showing the order of a manufacturing step for a semiconductor device according to the first embodiment of the invention;

FIG. 5 is a cross sectional view showing the order of a manufacturing step for a semiconductor device according to the first embodiment of the invention;

FIG. 6 is a cross sectional view of a completed semiconductor device according to the first embodiment of the invention;

FIG. 7 is a cross sectional view showing the order of a manufacturing step for a semiconductor device according to a second embodiment of the invention;

FIG. 8 is a cross sectional view showing the order of a manufacturing step for a semiconductor device according to the second embodiment of the invention;

FIG. 9 is a cross sectional view showing the order of a manufacturing step for a semiconductor device according to the second embodiment of the invention;

FIG. 10 is a cross sectional view showing the order of a manufacturing step for a semiconductor device according to the second embodiment of the invention;

FIG. 11 is a cross sectional view of a completed semiconductor device according to the second embodiment of the invention;

FIG. 12 is a cross sectional view showing the order of a manufacturing step for a semiconductor device according to a third embodiment of the invention;

FIG. 13 is a cross sectional view showing the order of a manufacturing step for a semiconductor device according to a fourth embodiment of the invention;

FIG. 14 is a cross sectional view of a completed semiconductor device according to third and fourth embodiments of the invention;

FIG. 15 is a cross sectional view showing the order of a manufacturing step for a semiconductor device according to a fifth embodiment of the invention;

FIG. 16 is a cross sectional view showing the order of a manufacturing step for a semiconductor device according to the fifth embodiment of the invention;

FIG. 17 is a cross sectional view showing the order of a manufacturing step for a semiconductor device according to the fifth embodiment of the invention;

FIG. 18 is a cross sectional view of a completed semiconductor device according to the fifth embodiment of the invention;

FIG. 19 is a cross sectional view showing the process of the manufacturing step for a semiconductor device according to a sixth embodiment of the invention;

FIG. 20 is a cross sectional view of a completed semiconductor device according to a seventh embodiment of the invention;

FIG. 21 is a cross sectional view showing the order of a manufacturing step for a semiconductor device according to an eighth embodiment of the invention;

FIG. 22 is a cross sectional view showing the order of a manufacturing step for a semiconductor device according to the eighth embodiment of the invention;

FIG. 23 is a cross sectional view showing the order of a manufacturing step for a semiconductor device according to the eighth embodiment of the invention;

FIG. 24 is a cross sectional view of a completed semiconductor device according to the eighth embodiment of the invention;

FIG. 25 is a cross sectional view showing the order of a manufacturing step for a semiconductor device according to a ninth embodiment of the invention;

FIG. 26 is a cross sectional view showing the order of a manufacturing step for a semiconductor device according to the ninth embodiment of the invention;

FIG. 27 is a cross sectional view of a completed semiconductor device according to the ninth embodiment of the invention;

FIG. 28 is a cross sectional view of a completed semiconductor device according to a tenth embodiment of the invention;

FIG. 29 is a cross sectional view of a completed semiconductor device according to a 11th embodiment of the invention;

FIG. 30 is a cross sectional view showing the process of the manufacturing step for a semiconductor device according to a 12th embodiment of the invention;

FIG. 31 is a cross sectional view showing the process of the manufacturing step for a semiconductor device according to a 13th embodiment of the invention; and

FIG. 32 is a cross sectional view showing the process of the manufacturing step for a semiconductor device according to the 13th embodiment of the invention.

### DESCRIPTION OF THE PREFERRED EMBODIMENTS

In the following embodiments, description is to be made divisionally for plural sections or embodiments, when necessary for the sake of convenience but they are relevant to each other except for the case described particularly, and they are in such a relation that one is a partial or entire modified example, details, or complementary description relative others.

Further, in the following embodiments, when the number of elements, etc. (including number, numerical values, quantity, range, etc.) are referred to, they are not restricted to the specified number and it may be more than or less than the specified number unless otherwise specified or apparently restricted to the specified number in view of the principle.

Further, in the following embodiments, it will be apparent that constituent elements (also including elemental steps) are not always essential excepting that they are otherwise specified or apparently essential in view of the principle.

In the same manner, in the following embodiments, when the shape of constitutional elements and positional relationship are referred to, they include those approximate to or similar with the shape or the like excepting that they are otherwise specified or apparently essential in view of the principle. This is identical also for the numerical values and ranges.

Further, throughout the drawings for describing the embodiments, those having identical functions carry same reference numerals for which duplicate description is to be omitted.

Now, preferred embodiments of the invention are to be described specifically with reference to the drawings. It will be apparent that the material, conduction type and manufacturing conditions for each of the portions are not restricted only to the descriptions for the embodiment but various modifications are possible.

<Embodiment 1>

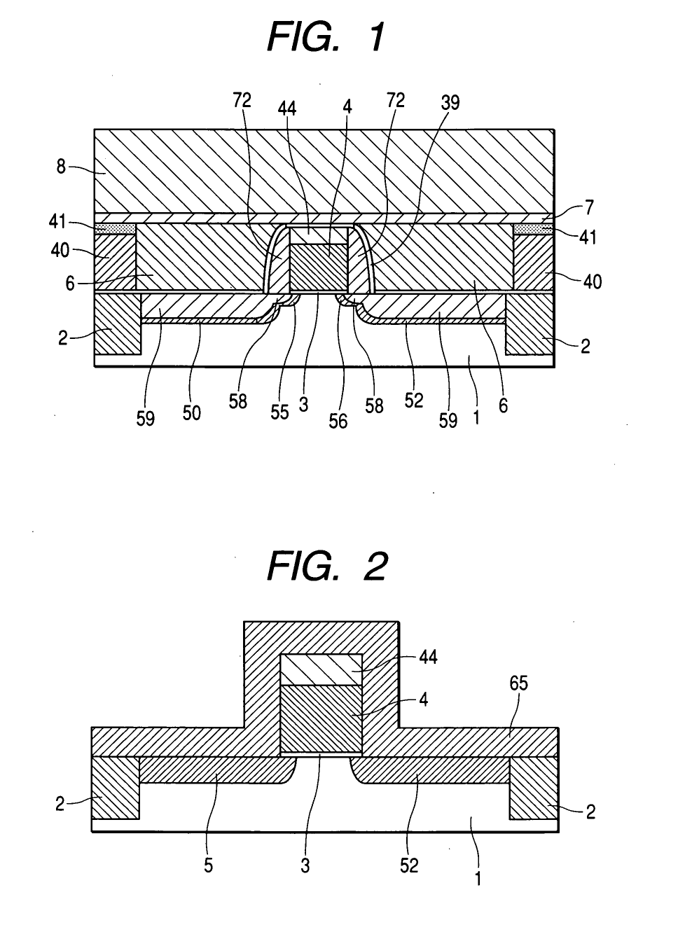

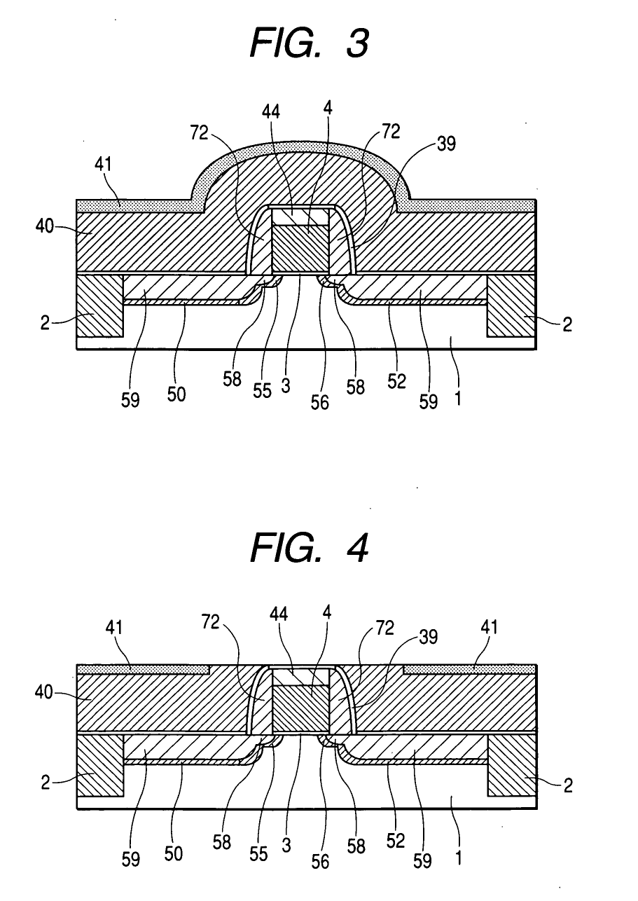

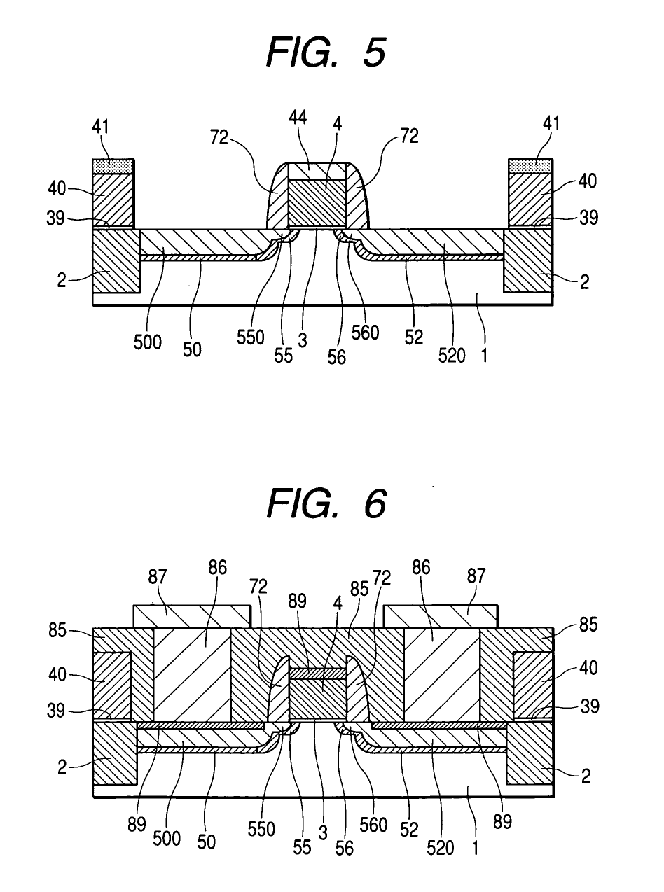

FIG. 3, FIG. 4, and FIG. 5 are cross-sectional views showing the process in the manufacturing steps for the semiconductor device having an IGFET as a constitutional element according to a first embodiment of the invention, in which FIG. 1 is a cross sectional view for a semiconductor device using an IGFET as a constituent element showing the state just before the laser anneal step and FIG. 6 is a cross sectional view for a completed IGFET. For the convenience of explanation, details for the manufacturing method are to be described mainly for an N-conduction type IGFET but a P-conduction type IGFET can also be manufactured in the same manner while replacing the ion implantation species to thereof the opposite conduction type. The method can be practiced easily also for a complementary IGFET by selective implantation of ion implantation species by selective arrangement of an ion implantation inhibitive mask. For a semiconductor substrate 1 comprising single crystal Si having a plane orientation (100), P-conduction type and 20 cm diameter, formation of an inter-device isolation insulation region 2 for defining an active region, ion implantation for controlling the threshold voltage, ion implantation for prevention of punch through and activating anneal therefor were conducted by a known manufacturing method for a semiconductor device. Further, a nitride film of 0.2 nm thickness was stacked and formed by forming a thermal oxide film of 1.8 nm thickness and nitriding the surface thereof with an NO gas to form a gate insulation film 3. The nitride film has a higher specific dielectric constant than that of the Si thermal oxide film and the optical film thickness electrically equivalent with that of the Si thermal oxide film corresponds to about twice thickness. Successively, after deposition of a polycrystalline silicon film of 90 nm thickness on the gate insulation film 3 and applying ion implantation of As at high concentration, a silicon nitride film was deposited to 10 nm thickness by a chemical vapor phase reaction method, and patterned to form a gate electrode 4 and a gate protection film 44 by a known manufacturing method for the IGFET. The width of the gate electrode, that is, the minimum value of the gate length was 60 nm, and the height of the gate electrode also including the gate protection insulation film 44 was 100 nm. After fabricating the gate electrode 4, As ions were ion implanted under the conditions at an acceleration energy of 3 keV and at an implantation dose of 4×10¹⁵/cm², by using the gate electrode 4 as an implantation inhibitive mask to form a shallower highly doped source diffusion layer 55 and a shallower highly doped drain diffusion layer 65 on a main surface region of the single Si layer 1. An amorphous layer 58 was formed to about 15 nm from the main surface of a semiconductor by the ion implantation. Prior to the ion implantation, Ge may be ion implanted at high concentration to control the depth of the amorphous layer 58 from the main surface of the semiconductor. For the ion implantation, an insulation film of 10 nm thickness or less may be left on the side wall of the gate electrode selectively and used as the implantation inhibition mask with no trouble. This method can vary the distance between the end of the gate electrode and the ends of the highly doped source and drain diffusion layers to control the punch through withstand voltage. Succeeding to the formation of the extremely shallower highly doped source and drain diffusion layers, a gate, electrode side wall insulation film 72 was selectively left only on the side wall of the gate electrode 4 by deposition of an Si oxide film of 30 nm thickness at a low temperature of 400° C. or lower and subsequent anisotropic dry etching, then As ions were implanted again to form a deeper source diffusion layer 50 and a deeper drain diffusion layer 52. In the ion implantation, the acceleration energy was 40 keV and the implantation dose was 4×10¹⁵/cm². An amorphous layer 59 was formed to about 70 nm from the main surface of the semiconductor by the ion implantation. In this state, a surface protection film 39 comprising an Al oxide film of 10 nm thickness was deposited for the entire surface at a low temperature of 400° C. or lower. The surface protection film was formed with an aim of preventing reaction between a metal film with high melting point deposited there over and an underlying semiconductor substrate by a laser irradiation anneal and with an aim of transferring heat to the underlying substrate. A material excellent in heat conductivity and chemical and thermal stability such as an Al oxide film, an Si nitride film, a layered film of an Al oxide film and an Si nitride film, and a layered film of an extremely thin Si oxide film and the thin film described above is preferred. After the deposition of the surface protection film 39 for the entire surface, an Si oxide film 40 of 90 nm thickness and an Si nitride film 41 of 20 nm thickness were deposited for the entire surface also at a low temperature of 400° C. or lower. The step is conducted at a low temperature of 400° C. or lower in order not to cause effective re-crystallization in the amorphous layers 58 and 59. The Al oxide film may comprise other Al compound such as an Al nitride film (FIG. 3).

From the state shown in FIG. 3, the Si nitride film 41 and the Si oxide film 40 protruding above the gate electrode 4 were removed selectively by chemical mechanical polishing. The end point for polishing was defined as at the surface of the Si nitride film 41 other than the region for the gate electrode 4 (FIG. 4).

From the state shown in FIG. 4, the Si oxide film 40 and the Si nitride film 41 of 20 nm thickness were formed with openings overstriding the gate electrode 4 by using a mask substantially corresponding to regions including entire source diffusion layer 50 and drain diffusion layer 52, that is, the region other than the region for the device isolation insulation film 2 to expose the surface of the Al oxide film 39. Successively, a laser energy absorbing film 6 comprising a titanium (Ti) film of 10 nm thickness and a tungsten (W) film of 80 nm thickness was continuously deposited by a sputtering method to fill the inside of the openings. From the state, the laser energy absorbing film 6 comprising the metal film with high melting point was polished by the chemical mechanical polishing method usually adopted in the connection manufacturing step of the semiconductor device. The end point of the polishing was controlled at the stage where the surface of the Si nitride film 41 was exposed. This is because the polishing rate for the silicon oxide film was only about 1/30 of the rate for the high melting metal film. The laser energy absorbing film 6 comprising the metal film with high melting point was selectively left only in the inside of the opening by the selective polishing. From the state, an anti-reactive film 7 comprising a TiN film was deposited for the entire surface to 10 nm thickness on the planarized surface and, successively, a silicon film of 50 nm thickness was deposited for the entire surface by a chemical vapor deposition reaction at a temperature of 400° C. or lower to form an anti-reflective film 8. The condition for the thickness of the anti-reflective film 8 was such that the energy absorptivity in the laser energy absorbing film reached the maximum. The thickness of the anti-reflective film may be 200 nm which is larger by λ/(2n than the thickness of the film where the reflectivity to the laser light is lowest as other film thickness with an optical point of view and with a view point of increasing latest heat in which λ represents the wavelength of the irradiation laser light and n represents the refractive index of the anti-reflective film. Preferably, the anti-preventive film is not amorphous but a polycrystalline Si film and the amorphous film may be crystallized through vapor deposition of nickel (Ni) or aluminum (Al) and subsequent heat treatment at low temperature of about 450° C. or lower. However, application of film deposition or anneal of Si film requiring 500° C. or higher is not preferred since the solid phase growing is started substantially by the anneal in a case where the amorphous region is present in the underlying portion and selective melting by the laser light irradiation can not be conducted. For the presence of the Si amorphous layer in the underlying substrate and maintaining the amorphous state, the highest allowable temperature is desirably 450° C. or lower, particularly, 400° C. or lower throughout the film deposition steps for the surface protection film, the laser energy absorption film 6 and the anti-reflective film 8. By way of the manufacturing steps described above, it is possible to design the thickness for each of the laser energy absorbing film 6 and the anti-reflective film 8 uniformly throughout the regions for the highly doped amorphous source and drain diffusion layers 58 and 59 and attain a constitution that the laser energy absorbing film 6 is not present on the gate electrode 4 and the device isolation insulation film 2. It is most important in the film constitution described above that the film thickness is constituted constant not depending on the underlying shape on the desired region such that the anti-reflective film 8 can be constituted uniformly on the planar underlying portion. While the energy reflectivity was about 64% and the energy absorptivity was 32% to the wavelength of the irradiation laser at 1064 nm in a case where the anti-reflective film 8 comprising Si is not present, the reflectivity is lowered substantially to zero and the energy absorptivity increases as far as 87% along with increase in the thickness of the anti-reflective film 8. As the thickness of the anti-reflective film 8 further increases, for example, to 125 nm, the reflectivity turns to increase to about 70% and the energy absorptivity is lowered, on the contrary, to 25%. Further, increase in the thickness of the anti-reflective film 8 now lowers the reflectivity and increases the absorptivity. That is, it is most important for keeping the heating distribution by the laser light irradiation constant to keep the thickness of the anti-reflective film 8 constant at 50 nm irrespective of the underlying shape relative to the wavelength of the irradiated laser at 1064 nm (FIG. 1)

From the state shown in FIG. 1 YAG laser using semiconductor laser excitation was irradiated, and the amorphous layers 58 and 59 of the highly doped underlying source and drain diffusion layers were melted and re-grown in solid phase by extremely short time heating of the laser energy absorbing film 6. The irradiation wavelength was 1064 nm, the half value width of the irradiation pulse was 90 ns, and the irradiation energy density was '420 mJ/cm². The irradiation area was 5×5 mm² and irradiation was conducted such that areas at the energy density of 95% or less of the maximum density overlapped with each other for the entire surface irradiation. In the melting process, impurities As were distributed again at a uniform box shaped highly doped profile of about 5×10²¹/cm³ in the molten area, to form extremely shallower box shaped highly doped diffusion layers 550 and 560, and deeper box shaped highly doped diffusion layers 500 and 520. The maximum doping gradient in the box shaped highly doped diffusion layer was 3 nm/dacade, and a further abrupt gradient was obtained than the maximum doping gradient of 4 nm/dacade just after ion implantation before activation. The impurity distribution just below the gate side wall insulation film at the end of the gate electrode was also confirmed to be a uniform box shaped highly doped impurity distribution by observation for the highly doped impurity distribution using the energy-dispersive spectroscopy by a cross-section transmission electro-microscopic observation for the specimen prepared separately. After the laser light irradiation treatment, the anti-reflective film 8 was removed by dry etching and the anti-reactive film 7, the laser energy absorbing film 6 and the Al oxide film 39 were removed by an etching solution selectively to expose the surfaces of the box shaped highly doped source and drain diffusion layers 500 and 520 (FIG. 5).

From the state shown in FIG. 5, after removing the left Si nitride film 44 to expose the surface of the gate electrode 4, selective formation of a Co silicide film 89 on the gate electrode 4, and the source and drain diffusion layers 500 and 520, deposition and planarization by polishing for the second inter-connection insulation film 85, opening at desired regions, burying of the connection metal 86 into the openings and planarization and wiring steps including the source electrodes 87 and the drain electrodes 88 were conducted according to a known manufacturing method for a semiconductor device comprising the IGFET as a main constitutional factor to manufacture a semiconductor device (FIG. 6).

In the cross sectional transmission electrodemicroscopic observation of the semiconductor device manufactured by way of the manufacturing method described above, no crystal defects were observed in all the source and drain diffusion layers 50, 500, 55, 550, 52, 520, 56, and 560 not depending on the distance from the end of the gate electrode. As described above, the crystal state in the region where the amorphous layer of the highly doped source and drain layers are melted and re-grown in the solid phase is quite different from that in the current technique in which crystal defects left by the boundary ion implanting range or crystal defects such as presence of loop dislocations or twins observed usually in solid phase growing from the amorphous layer by high temperature short time anneal. On the other hand, for the source and drain junction, correlation exists between the box shaped highly doped impurity distribution having such an abrupt impurity distribution with the difference of the doped concentration in the impurity distribution for one digit within a range of 2 to 3 nm, and the crystal form and no defects were observed at all under the transmission electron microscopic observation in the region where the box shaped highly doped impurity distribution was attained. On the other hand, either twins or defects at ion injection end was observed under the insufficient heating condition not attaining the highly doped box shaped impurity distribution. Further, failure of loss of pattern caused by evaporation of the gate electrode or the like was not present at all. Further, no fluctuation was observed for the threshold voltage caused by the leakage of the impurities added to the gate electrode through the gate insulation film 3 and it was confirmed that heating of the gate electrode by the laser irradiation was sufficiently suppressed. A correlation was found between the occurrence of the impurity leak diffusion or degradation of the gate insulation film regarding the gate electrode and the crystal form of the gate electrode, and impurity leakage diffusion or deterioration of gate insulation film was surely observed in the liquid phase grown polycrystalline silicon re-crystallized by way of the molten state. Occurrence of the impurity leak diffusion or deterioration of gate insulation film was suppressed only in the silicon gate electrode having the hysteresis of solid phase growing and it is desirable to have a hysteresis of solid phase growing with a view point of the crystal form. Accordingly, with a view point of the crystal structure for the integrated circuit after the laser anneal, it is preferred that the gate electrode is polycrystals based on the solid phase growing, while the source and drain junction region is intact crystals not having twins crystal or ion injection end defects. In this embodiment, while description has been made to the Si film as the anti-reflective film 8, the film may be replaced by a Ge film or a Si and Ge mixed film to obtain same effects. In a case where the semiconductor device applied with this embodiment is constituted with source and drain junction regions of different areas at several positions, since the heat capacity differs depending on the difference of the occupying area in the laser energy absorbing film 6, this causes a pattern depending phenomenon that the melting condition depends on the occupying area and the regions of small area is not melted sufficiently under constant irradiation energy condition. In order to solve the pattern dependence, laser light is irradiated at a higher irradiation energy selectively to a group of minute regions in which the occupying area of the laser energy absorbing film 6 is small (for example, memory array region) and then laser light is irradiated again at a somewhat lower irradiation energy for the entire region including the region described above and the group of the laser energy absorbing film 6 of large occupying area (for example, peripheral circuit region). Irradiation of the laser light being overlapped for the group of regions with small occupying area in the laser energy absorbing film 6 was conducted under the condition where the region of larger area was sufficiently melted and activated. In the region where the laser light irradiation is overlapped, the amorphous region was already crystallized by the first laser light irradiation and the effect of the overlapped irradiation is negligible and the entire region could be activated by laser light irradiation while overcoming the area dependence also in a semiconductor device having source and drain junction regions of different regions at several locations.

<Embodiment 2>

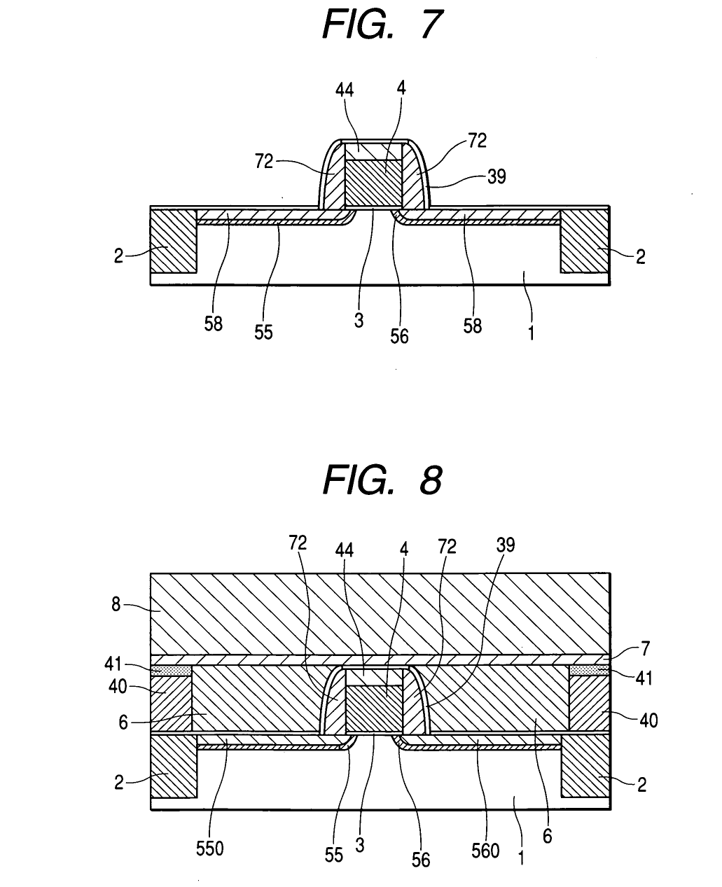

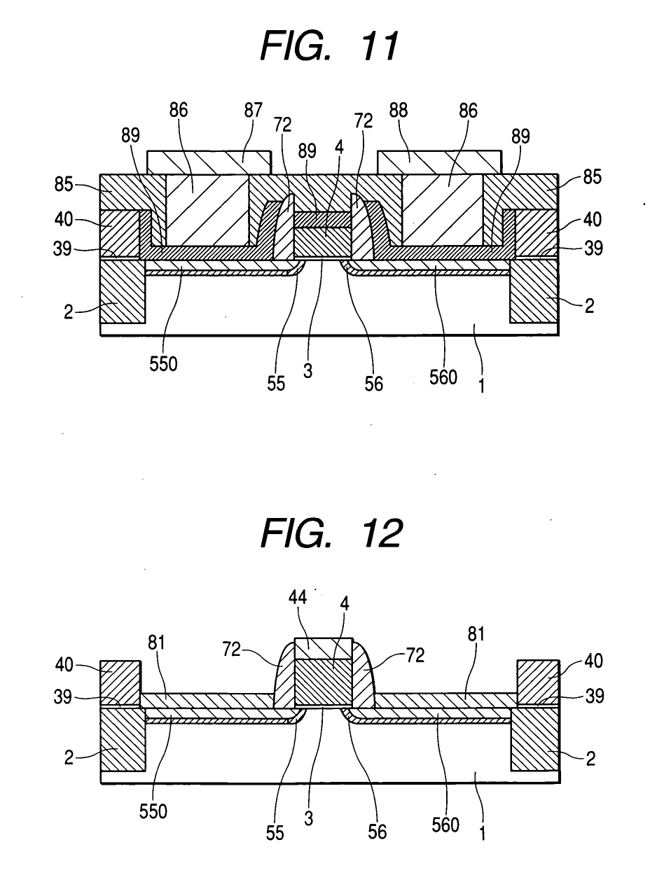

FIG. 7 to FIG. 10 are cross sectional views showing the order of manufacturing steps for an N-conduction type IGFET as a constitutional element of a semiconductor device according to a second embodiment of the invention, and FIG. 11 is a cross sectional view for the completed state thereof. The process was practiced till the entire surface deposition of the surface protection film 39 comprising the Al oxide film in accordance with Embodiment 1 but the step of forming the deeper source and drain diffusion layers 50 and 52 and the deep amorphous layer 59 were not conducted (FIG. 7).

From the state shown in FIG. 7, in accordance with Embodiment 1, an Si oxide film 40 and an Si nitride film 41 were deposited for the entire surface, and opening was formed to the Si oxide film 40 and the Si nitride film 41 overstriding the gate electrode 4 by using a mask substantially corresponding to the region including entire source diffusion layer 50 and drain diffusion layer 52 to expose the surface of the Al oxide film 39. Successively, in accordance with Embodiment 1, the laser energy absorbing film 6 was deposited continuously to fill the inside of the opening and the laser energy absorbing film 6 was polished to expose the surface of the Si nitride film 41. Successively, after depositing an anti-reactive film 7 comprising a TiN film for the entire surface at 10 nm thickness and depositing an amorphous silicon film 8 for the entire surface at 50 nm thickness by chemical vapor phase reaction at a temperature of 400° C. or lower, the laser light irradiation was applied also in accordance with Embodiment 1 to form extremely shallower box shaped highly doped source and drain layers 550 and 560 by melting and solid phase re-growing of the extremely shallow amorphous layer 18 (FIG. 8).

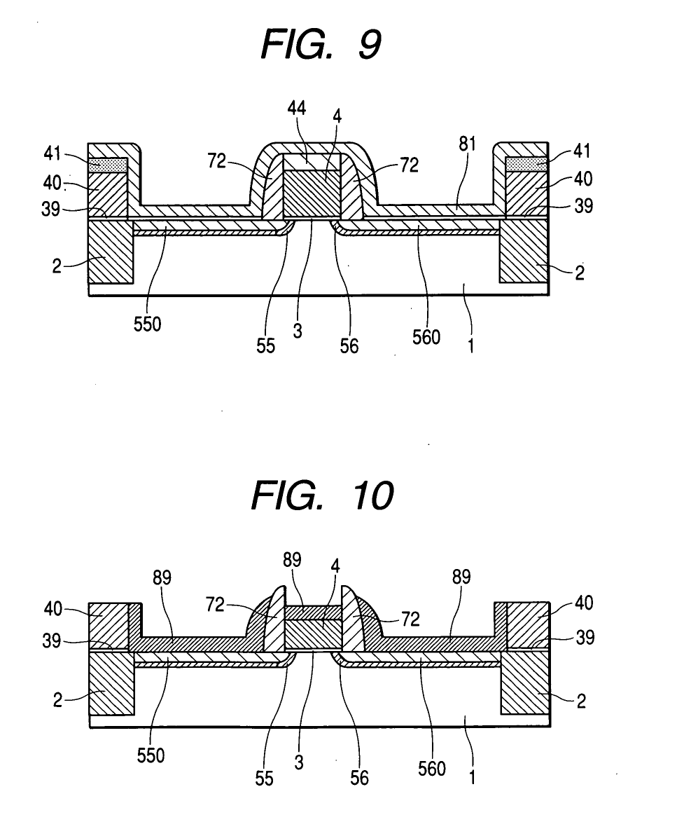

From the state shown in FIG. 8, the anti-reflective film 8 was removed by dry etching and the anti-reactive film 7, the laser energy absorbing film 6 and the surface protection film 39 were removed by an etching solution selectively to expose the surface of the extremely shallower box shaped highly doped source and drain diffusion layers 550 and 560. Successively, an Si film 81 of 20 nm thickness was deposited for the entire surface by chemical vapor phase reaction. N-conduction type impurities such as As or P may be introduced if desired by an optional amount to the Si film 81 by an ion implantation method or the like (FIG. 9).

From the state shown in FIG. 9, the Si film 81 protruded on the Si nitride film 41 was selectively removed by chemical mechanical polishing. The end point of polishing was defined as at the surface of the Si nitride films 41 and 44. The Si nitride films 41 and 44 were selectively removed by a phosphoric acid solution in which the Si film 81 was etched somewhat. Then, according to the known IGFET manufacturing method, the exposed Si film 81 was entirely transformed together with the surface portion of the gate electrode 4 into a Co silicide film 89, further, a second inter-connection insulation film 85 was deposited and planarized by polishing and opened at a desired region, a connection metal 86 was buried in the opening and planarized, and the wiring step including the source electrode 87 and the drain electrode 88 was conducted, to manufacture a semiconductor device (FIG. 11).

By way of the manufacturing steps described above, a micro-refined IGFET in which the source and drain regions are formed by the diffusion layers 550 and 560 having the extremely shallower box shaped highly doped distribution and the silicide film 89 stacked and arranged thereon. With the constitution described above, in the present micro-refined IGFET, ion implantation for forming deeper source and drain diffusion layers was no more necessary and this moderated restriction to the height of the gate electrode, which was the essential condition as a shield for deep source and drain implanted ions. Accordingly, a micro-refined IGFET having a lower gate height as the essential condition for the fabrication of a shorter gate length was enabled. Specifically, the gate electrode could be constituted by a thin Si film of 30 nm to 40 nm or less enabling shielding of implanted ions for forming extremely thin source and drain regions 55 and 56 for attaining an IGFET having a micro-refined gate length of 10 nm.

In the semiconductor device according to this embodiment, it is necessary that the height of the gate electrode is made lower and that combined use with the stacked source and drain structure is enabled for fabricating a more refined gate electrode. In the semiconductor device according to this embodiment, short circuit between the gate electrode and the source and drain electrodes was prevented by making the height for the gate side wall insulation film to higher than the height of the gate electrode.

In the formation of the diffusion layers 550 and 560 having the extremely shallower box shaped highly doped distribution according to this invention, since the laser energy absorbing film 6 could be designed uniformly in all the regions above the shallower amorphous layer 58 irrespective of the shape of the underlying portion, further abrupt gradient was attained in the entire region including the regions just below the gate side wall insulation film 72, and the region in which the size relative to the gate electrode is minimum, at a uniform box shaped high doping concentration of about 5×10²¹/cm³ and a maximum doping gradient of 3 nm/decade in the impurity distribution which was further abrupt than the maximum doping gradient of 4 nm/decade just after ion implanted before activation. Also under the cross sectional transmission electron microscopic observation, no crystal defects were observed at all in the source and drain diffusion layers 500 and 560 in all the regions not depending on the distance from the end of the gate electrode. Further, failure of loss of pattern caused by evaporation of the gate electrode, etc. was not present at all. Furthermore, fluctuation of the threshold voltage caused by leakage of impurities added to the gate electrode to the substrate by way of the thin gate insulation film 3 was not observed, and it was confirmed in the same manner as in Embodiment 1 that heating of the gate electrode by laser irradiation was effectively suppressed.

In the manufacturing steps described above, after ion implantation of AS forming the extremely shallower source and drain diffusion layers 55 and 56, and formation of the gate electrode side wall insulation film 72, a semiconductor device with additional implantation of P (phosphorus) ions having an N-conduction type at an implantation dose such that the maximum impurity concentration is attained near the junction depth of the source and drain diffusion layers 55 and 56 and so as to compensate implantation of P-conduction type ions for preventing punch through was also manufactured trially (not illustrated). Additional P (phosphorus) ion implantation lowers the effective impurity concentration at the bottom of the junction region of the extremely shallower source and drain junction to attain higher operation speed of the semiconductor device due to the lowering of the junction capacitance. Particularly, in the micro-refined IGFET not having deeper source and drain junction as in the semiconductor device of this embodiment, it is possible for device design not causing punch through current component between deeper source and drain regions, only considering the punch through component near the semiconductor surface, thereby capable of lowering the parasitic capacitance component at the bottom of the extremely shallower junction.

<Embodiment 3>

FIG. 12 is across-sectional view showing the manufacturing step in the course of manufacturing an N-conduction type IGFET as a constituent element for a semiconductor device according to a third embodiment of the invention, and FIG. 14 is a cross sectional view in the completed state thereof. In accordance with Embodiment 2, diffusion layers 550 and 560 having an extremely shallower box shaped highly doped distribution were formed by YAG laser irradiation, the anti-reflective film 8 was removed by dry etching, and the anti-reflective film 7, the laser energy absorbing film 6 and the surface protection film 39 were removed by an etching solution selectively to expose the surface of the extremely shallower box shaped highly doped source and drain diffusion layers 550 and 560. Further, the exposed Si nitride films 41 and 44 were selectively removed. In this state, an Si film 81 of 20 nm thickness was deposited only on the exposed Si surface selectively by a known selective epitaxial method. N-conduction type impurities such as As or P may also be introduced by an optional amount into the Si film 81, for example, by an ion implantation method as required (FIG. 12).

From the state shown in FIG. 12, all the exposed Si film 81 was transformed into a Co silicide film 89 in accordance with Embodiment 2, the second inter-connection insulation film 85 was deposited and polished by planarization, opened at desired regions, a connection metal 86 was buried into the opening and planarized, and a wiring step including the source electrode 87 and the drain electrode 88 was conducted to manufacture a semiconductor device (FIG. 14).

Also in the semiconductor device manufactured according to this embodiment, a micro-refined IGFET in which the source and drain regions are constituted with the diffusion layers 550 and 560 having the extremely shallower box shaped highly doped distribution and the silicide film 89 stacked and arranged thereon was manufactured in the same manner as the semiconductor device according to Embodiment 2. With the constitution described above, in the present micro-refined IGFET, ion implantation for forming deeper source and drain diffusion layers was no more necessary and this moderated restriction to the height of the gate electrode, which was the essential condition as a shield for deep source and drain implanted ions. Accordingly, a micro-refined IGFET having a lower gate height as the essential condition for the fabrication of a shorter gate length was enabled. Specifically, the gate electrode could be constituted by a thin Si film of 30 nm to 40 nm or less enabling shielding of implanted ions for forming extremely thin source and drain regions 55 and 56 for attaining an IGFET having a micro-refined gate length of 10 nm.

In the formation of the diffusion layers 550 and 560 having the extremely shallower box shaped highly doped distribution according to this invention, since the laser energy absorbing film 6 could be designed uniformly in all the regions above the shallow amorphous layer 58 irrespective of the shape of the underlying portion, further abrupt gradient was attained in the entire region including the regions just below the gate side wall insulation film 72, and the region in which the size relative to the gate electrode is minimum, at a uniform box shaped high doping concentration of about 5×10²¹/cm³ and a maximum doping gradient of 3 nm/decade in the impurity distribution which was further abrupt than the maximum doping gradient of 4 nm/decade just after ion implanted before activation. Also under the cross sectional transmission electron microscopic observation, no crystal defects were observed at all in the source and drain diffusion layers 500 and 560 in all the regions not depending on the distance from the end of the gate electrode. Further, failure of loss of pattern caused by evaporation of the gate electrode, etc. was not present at all. Furthermore, fluctuation of the threshold voltage caused by leakage of impurities added to the gate electrode to the substrate by way of the thin gate insulation film 3 was not observed, and it was confirmed in the same manner as in Embodiment 2 that heating of the gate electrode by laser irradiation was effectively suppressed.

<Embodiment 4>

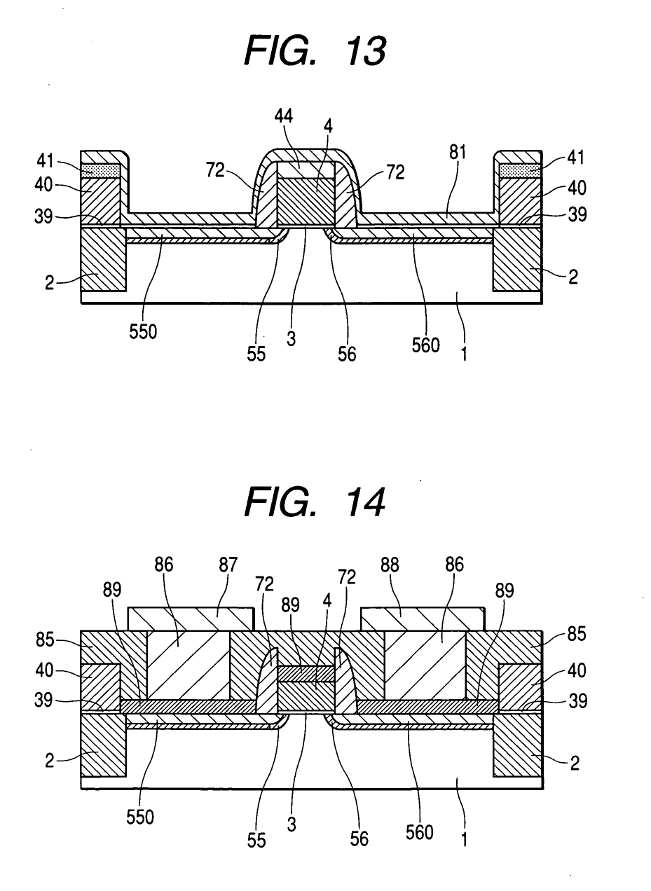

FIG. 13 is a cross sectional view showing the step in the course of manufacturing an N-conduction type IGFET as a constituent element of a semiconductor device according to a fourth embodiment of the invention and FIG. 14 is a cross sectional view for the completed state thereof. In the deposition of the Si film 81 in Embodiment 3, a remote sputtering method was used instead of the selective epitaxial method, and an Si film 81 was deposited to 20 nm thickness in this embodiment. The Si film 81 deposited by the remote sputtering method has different film thickness based on the shape of the underlying substrate and the thickness on the side wall of a convex-shaped underlying substrate relative to the thickness on the flat underlying substrate is about 1/10. Other means having the directionality in view of the deposition film thickness depending on the shape of the underlying substrate includes a collimator sputtering method, a catalytic chemical vapor phase reaction method or an ion vapor deposition method, and such anisotropic deposition method may also be practiced with no problem (FIG. 13).

From the state shown in FIG. 13, the Si film 81 on the Si nitride films 41 and 44 were selectively removed by chemical mechanical polishing, the Si film 81 deposited on the side wall of the convex shaped underlying substrate, that is, the side wall of the gate electrode was removed by etching using a phosphoric acid solution. Then, the exposed Si film 81 was entirely transformed into a Co silicide film 89 in accordance with Embodiment 3 and, further, the second inter-connection insulation film 85 was deposited and planarized by polishing, opened at desired regions, a wiring metal 86 was buried into the openings and planarized, and the wiring step including the source electrode 87 and the drain electrode 88 was conducted to manufacture a semiconductor device (FIG. 14).

Also in the semiconductor device manufactured in accordance with this embodiment, a micro-refined IGFET in which source and drain regions are constituted with the diffusion layers 550 and 560 having extremely shallower box shaped highly doped distribution and the silicide film 89 stacked and arranged thereon was manufactured in the same manner as the semiconductor device according to Embodiment 3. With the constitution described above, in the present micro-refined IGFET, ion implantation for forming deeper source and drain diffusion layers was no more necessary and this moderated restriction to the height of the gate electrode, which was the essential condition as a shield for deep source and drain implanted ions. Accordingly, a micro-refined IGFET having a lower gate height as the essential condition for the fabrication of a shorter gate length was enabled. Specifically, the gate electrode could be constituted by a thin Si film of 30 nm to 40 nm or less enabling shielding of implanted ions for forming extremely thin source and drain regions 55 and 56 for attaining an IGFET having a micro-refined gate length of 10 nm. In the formation of the diffusion layers 550 and 560 having the extremely shallower box shaped highly doped distribution according to this invention, since the laser energy absorbing film 6 could be designed uniformly in all the regions above the shallow amorphous layer 58 irrespective of the shape of the underlying portion, a further abrupt gradient was attained in the entire region including the regions just below the gate side wall insulation film 72, and the region in which the size relative to the gate electrode is minimum, at a uniform box shaped high doping concentration of about 5×10²¹/cm³ and a maximum doping gradient of 3 nm/decade in the impurity distribution which was further abrupt than the maximum doping gradient of 4 nm/decade just after ion implanted before activation. Also under the cross sectional transmission electron microscopic observation, no crystal defects were observed at all in the source and drain diffusion layers 500 and 560 in all the regions not depending on the distance from the end of the gate electrode. Further, failure of loss of pattern caused by evaporation of the gate electrode, etc. was not present at all. Furthermore, fluctuation of the threshold voltage caused by leakage of impurities added to the gate electrode to the substrate by way of the thin gate insulation film 3 was not observed, and it was confirmed in the same manner as in Embodiment 3 that heating of the gate electrode by laser irradiation was effectively suppressed.

<Embodiment 5>

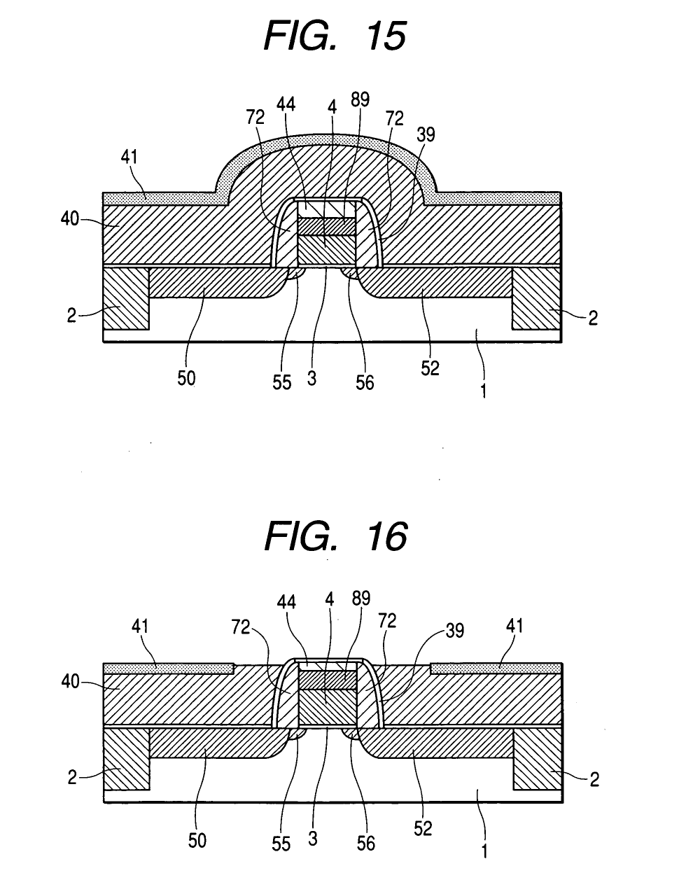

FIG. 15 to FIG. 17 are cross sectional views showing the order of the steps for manufacturing an N-conduction type IGFET as a constituent element of a semiconductor device according to the fifth embodiment of the invention and FIG. 18 is a cross sectional view for the completed state thereof. In Embodiment 1, the Si film was used for the gate electrode structure and a so-called silicide structure of simultaneously siliciding the surface of the film together with the surface of the source and drain diffusion layers was used. However, in this embodiment, a layered film of an Si film 4 and a W (tungsten) silicide film 89 was previously formed into a gate electrode as a gate electrode structure, and used as an implantation mask for ion implantation to the source and drain diffusion layers, and the process was conducted up to the formation of a deeper source diffusion layer 50 and a deeper drain diffusion layer 52. In this embodiment, known spike annealing (1100° C.) was applied in this state to activate extremely shallower source diffusion layer 55 and drain diffusion layer 56 and deeper source diffusion layer 50 and deeper drain diffusion layer 52 simultaneously. Successively, in accordance with Embodiment 1, a surface protection film 39 comprising an Al oxide film was deposited for the entire surface and an Si oxide film 40 and an Si-nitride film 41 were deposited for the entire surface (FIG. 15).

From the state shown in FIG. 15, the Si nitride film 41 and the Si oxide film 40 protruded above the gate electrode 4 were selectively removed by chemical mechanical polishing. The end point for the polishing was defined as at the surface of the Si nitride film 41 other than the region of the gate electrode 4 (FIG. 16).

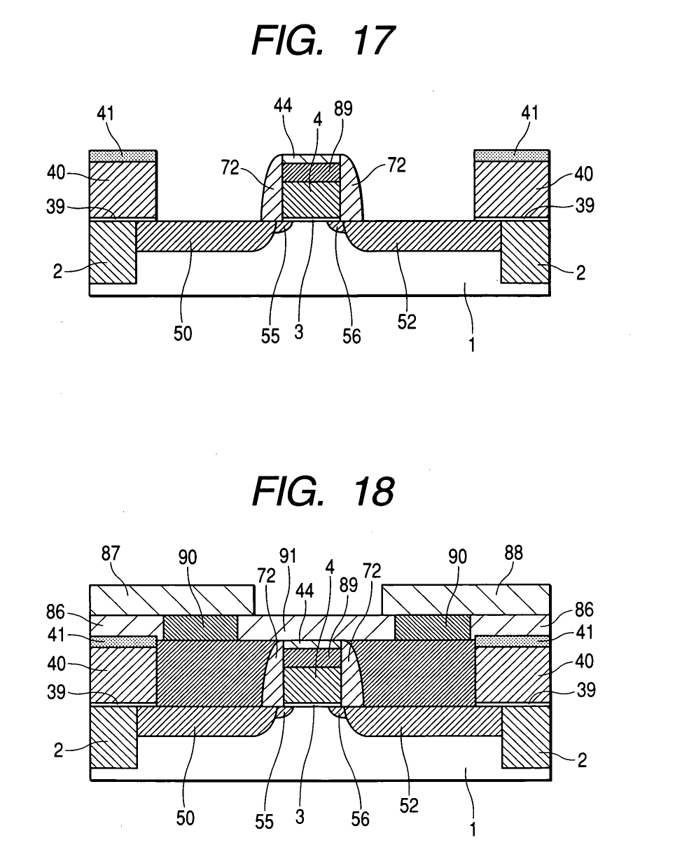

From the state shown in FIG. 16, the Si oxide film 40 and the Si nitride film 41 were opened overstriding the gate electrode 4 by dry etching using a mask substantially corresponding to the region including the entire source diffusion layer 50 and the drain diffusion layer 52, that is, the region other than the region for the inter-device isolation insulation film 2. An Al oxide film 39 was used as a dry etching stopping film and, after exposing the surface of the Al oxide film 39, the Al oxide film 39 was selectively removed by a phosphoric acid solution (FIG. 17).

From the state shown in FIG. 17, a metal film of 10 nm thickness comprising layered TiN film and W film was deposited so as to completely fill the openings by chemical vapor phase reaction, the metal film left on the Si nitride film 41, etc. was removed by the chemical mechanical polishing and left selectively only in the inside of the opening to form a connection metal 86 in the contact hole. Successively, a second inter-connection insulation film 91 was deposited and the insulation film was opened according to a desired circuit constitution, and the connection metal 90 inside the contact hole was formed by filling a metal side film in the opening and selectively leaving the same to the inside of the opening by chemical mechanical polishing. Further, a wiring step including a source electrode 87 and a drain electrode 88 was conducted in accordance with a desired circuit structure to manufacture a semiconductor device comprising an IGFET as a main constituent element (FIG. 18).

In the semiconductor device manufactured according to this embodiment, since connection with the connection metal can be conducted for the entire surface of the diffusion layer without applying silicidation to the diffusion layers for connection with the source and drain diffusion layer, contact resistance can be decreased and, accordingly, the series resistance of the transistor can be decreased, that is, operation at larger current and higher speed can be attained. This can overcome the problem of local junction failure caused by silicidation for the surface of the diffusion layer in the existent device, and improve the yield for good products and improve the reliability. In the opening for the Si oxide film 40, the gate electrode was partially exposed in the dry etching opening step except for the Si nitride film which was sufficiently thick as the gate side wall insulation film 72 to result in the problem of short circuit between the gate electrode and the source or drain connection electrode in the prior art. However, in the semiconductor device manufactured according to this embodiment, since the dry etching for opening can be suppressed only by the thin Al oxide film 39, restriction on the thickness and the material of the gate sidewall insulation film 72 can be solved entirely according to this embodiment. Therefore, in the semiconductor device according to this embodiment, use of the gate side wall insulation film by the Si oxide film of high dielectric constant can also provide the effect of reducing the parasitic capacitance between the gate and the source or between the gate and the drain, that is, attaining higher speed operation. Further, since various kinds of insulation films can be used as the gate side wall insulation film 72, the performance and the reliability can be improved based on the control for the stress and the control for the line of electric force at the gate fringe in the active regions.

<Embodiment 6>

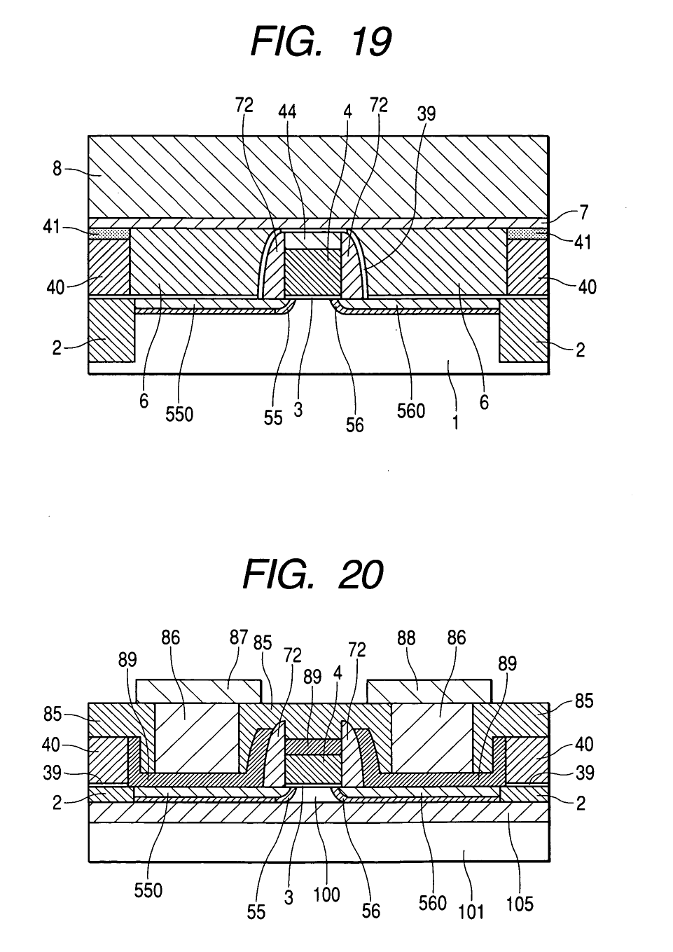

FIG. 19 is a cross sectional view showing the state just before applying the step of a laser anneal to an N-conduction type IGFET as a constituent element of a semiconductor device according to a sixth embodiment of the invention. In Embodiment 2 described above, the surface protection film 39 comprising the Al oxide film has a constitution provided both with the function as an etching stopper film in the dry etching for opening the Si oxide film 40 and a good conduction film for the heat from the laser energy absorbing film during laser irradiation but the optimal film thickness conditions for the both functions are not always identical. In the manufacture of the semiconductor device according to this embodiment, after opening the Si oxide film 40 in Embodiment 2, a layered film 39 comprising an Si nitride film of 3 nm thickness and an Al oxide film of 5 nm thickness was additionally formed to the surface of an amorphous layer 58 and then a laser energy absorbing film 6 was deposited and planarized, an anti-reactive film 7 and an anti-reflective film 8 were deposited, and the diffusion layer was activated by the irradiation of the laser light in accordance with Embodiment 2 (FIG. 19).

From the state shown in FIG. 19, after removing the anti-reflective film 8, the anti-reactive film 7, the laser energy absorbing film 6, and the layered film 39 in accordance with Embodiment 2, a semiconductor device comprising IGFET as a main constituent element was successively manufactured according to Embodiment 2.

In the semiconductor device manufactured according to this embodiment, since the layered constitution and the thickness of the surface protection film 39 can be set independently of the fabrication conditions for the inter-connection insulation film 400 optionally corresponding to the setting for the laser energy to be irradiated, a film constitution enabling more efficient heat transmission characteristic corresponding to the depth of the diffusion layer (amorphous layer) to be activated, etc. can be attained, and the applicable condition to the activation of the diffusion layer by the laser light irradiation can be extended to a wider range.

<Embodiment 7>

FIG. 20 is a cross sectional view for the completed state of an N-conduction type IGFET as a constituent element of a semiconductor device according to the seventh embodiment of the invention. A semiconductor device was manufactured by using a support substrate 101 and a single crystal Si film 100 of 10 nm thickness formed on a buried oxide film 105 of 200 nm thickness instead of the semiconductor substrate 1 comprising single crystal Si in Embodiment 2. The single crystal Si film of the structure described above has a feature in that unitary IGFETs constituting the semiconductor device are completely isolated from each other by an inter-device isolation insulation film 2 referred to as SOI (Silicon On Insulator) and the buried oxide film 105. Further, since the diffusion layer capacitance is in serial connection with the thick buried oxide film capacitance in the constitution that the bottom component of source and drain diffusion layers 56, 56, 550, and 560 or the bottom face component of the depletion layer in a state of applying electric field is in contact with the buried oxide film 105, the parasitic capacitance can also be decreased to provide outstanding characteristics of higher operation speed and low power consumption.

In the semiconductor device manufactured according to this embodiment, similar activation effect could be obtained even when the laser irradiation energy was lowered to about ⅔ of the energy required for the activation of the source and drain diffusion layer in Embodiment 2. This is considered that since the heat required for the activation of the diffusion layers 55, 56, 550, and 560 is less dissipated to the support substrate 101 due to the presence of the buried oxide film 105 and, accordingly, the amorphous layer is heated sufficiently even under the irradiation of laser light at lower energy.

For the single crystal Si film 100 constituting the semiconductor device according to this embodiment, it has been described to a case that IGFET of an extremely thin 10 nm thickness and of a completely depletion type is a constituent element. However, this is also applicable to a case where the film thickness is 100 nm or more and a so-called partial depletion type IGFET is a constituent element. In this embodiment, an example of using the SOI substrate instead of the semiconductor substrate 1 comprising single crystal Si was shown but a polycrystal Si film constituted on a glass substrate may be used instead of the semiconductor substrate 1 comprising the single crystal Si. Further, a quartz substrate may be used instead of the glass substrate 110, and a crystal substrate of a structure having a single crystal Si film instead of the polycrystal silicon film may also be used. The latter is marketed as a so-called wafer bonding technique and causes no problem at all except for the expensive cost.

<Embodiment 8>

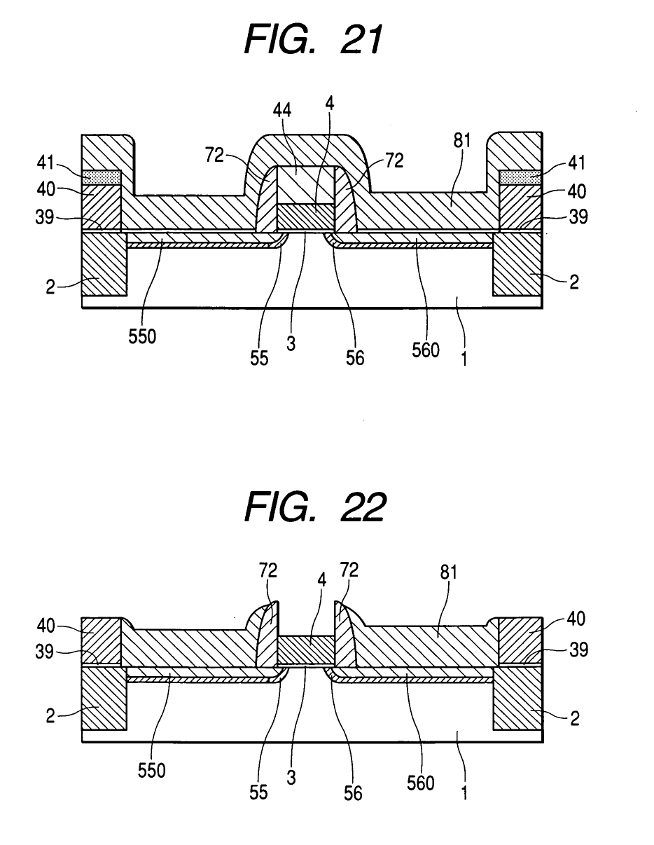

FIG. 21 to FIG. 23 are cross sectional views showing the order for the steps of manufacturing an N-conduction type IGFET as a constituent element of a semiconductor device according to an eighth embodiment of the invention, and FIG. 24 is a cross sectional view for the completed state thereof. In accordance with the Embodiment 2, a gate electrode 4 and a gate protection insulation film 44 were patterned. In this embodiment, a layered insulation film comprising a polycrystal Si film of 50 nm thickness, a silicon oxide film of 10 nm thickness and a silicon nitride film of 40 nm thickness was patterned into a gate electrode 4 and a gate protection film 44 respectively. In this embodiment, impurity introduction for lowering the resistance of the polycrystal Si film was saved. Then, in accordance with Embodiment 2, after conducting a laser light irradiation heat treatment from the formation of a shallower highly doped source diffusion layer 55 and a shallower highly doped drain diffusion layer 56 including a shallow amorphous layer 58, formation of a gate side wall insulation film 72 to the formation of extremely shallower box shaped highly doped diffusion layers 550 and 560, activation of the diffusion layer, and selective removal of materials such as the laser energy absorbing member 6 and the anti-reflective film 8 used for the laser light irradiation anneal, a highly P-doped Si film 81 of 80 nm thickness was deposited for the entire surface. In a case of a complementary IGFET, a layered film of a highly B-doped Si film and an Si oxide film was deposited and patterned to selectively leave the same on the P-conduction type IGFET region and, successively, a P-added Si film was deposited and patterned on an N-conduction type IGFET region to selectively leave the same and then the Si oxide film may be removed (FIG. 21).

From the state shown in FIG. 21, the Si film 81 deposited on the inter-connection insulation film 400 was selectively removed by chemical mechanical polishing with the silicon nitride film 41 being defined as a polishing end point. Then, the silicon nitride film 41 was selectively removed by a hot phosphoric acid solution to expose also the surface of the gate electrode 4. In this step, the Si film 81 was also etched slightly (FIG. 22).

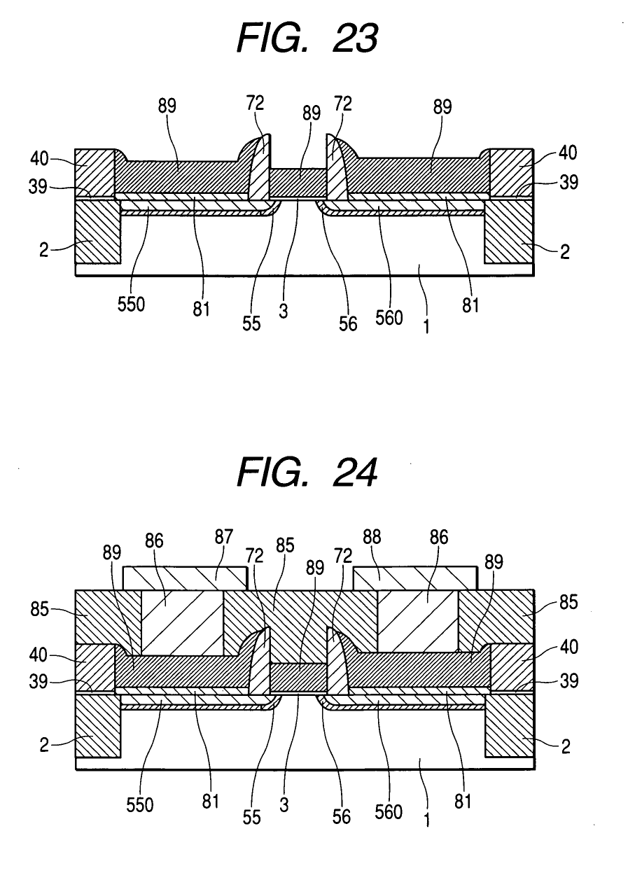

From the state shown in FIG. 22, the Si film 81 and the gate electrode 4 were applied with silicidation by Co according to Embodiment 2. In this embodiment, the gate electrode 4 of 50 nm thickness was entirely silicided into a metal silicide gate electrode. In this step, the Si film 81 was left below the metal silicide film 89 above the source and drain diffusion layers, and it does not reach the extremely shallower box shaped highly doped diffusion layers 550 and 560 (FIG. 23).

From the state shown in FIG. 23, in accordance with Embodiment 2, a second inter-connection insulation film 85 was deposited and planarized by polishing, and opened at desired regions, a connection metal 86 was buried into the openings and planarized and a wiring step including a source electrode 87 and a drain electrode 88 was conducted to manufacture a semiconductor device (FIG. 24).

The semiconductor device manufactured according to this embodiment has all the features of the semiconductor device according to Embodiment 2. In addition, since a micro-refined metal silicide film gate electrode maintaining the fabrication accuracy for the Si gate electrode can be constituted, the problem in the Si gate electrode, that is, increase in the effective thickness of the gate film caused by the depletion of the gate electrode, that is, relative lowering of the driving current at a constant power source voltage can be dissolved and a large current can be attained even for a low voltage power source. Specifically, in the existent semiconductor device of the Si gate electrode, since the effective thickness of the gate insulation film appearing as an electric capacitance relative to the physical thickness of the gate insulation film was effectuated more by about 0.8 nm in view of the Si oxide film by the gate depletion. However, in the semiconductor device of this embodiment. The physical thickness and the electrical thickness of the gate insulation film could be made substantially identical.

Further, in the semiconductor device according to this embodiment, since the resistance is lowered to about ⅕ of the existent Si silicide gate electrode even with no addition of highly doped impurity to the gate electrode, failure of the scattering of the threshold voltage caused by punch through of highly doped additive impurities, particularly, boron in the gate electrode in the P-conduction type IGFET through the gate insulation film could be overcome substantially. Further, in the semiconductor device according to this embodiment, since the gate electrode material was made of a metal silicide film, the threshold voltage value was increased by about 0.5 V due to the difference of the work function from that of the Si gate electrode. While injection of highly doped channel impurities was inevitable for preventing lowering of the threshold voltage value in the existent micro-refined semiconductor device and, accordingly, lowering of the mobility caused by the scattering of the impurities was inevitable so far, injection of the high concentration channel impurities was no more necessary. That is, in the semiconductor device according to this embodiment, the driving current could be increased due to the decrease in the concentration of the channel impurities. In this case, it will be apparent that attainment of the source and drain diffusion layers comprising the extremely shallower box shaped highly doped diffusion layer can provide an epoch making role for the suppression of punch through current, that is, prevention of the short channel effect and outstanding decrease in the serial resistance. In this embodiment, the silicide film on the source and drain diffusion layers can be constituted so as not to reach the inside of the semiconductor substrate. This can also prevent the metal silicide film from punching through the extremely shallower junction to cause junction failure.

<Embodiment 9>

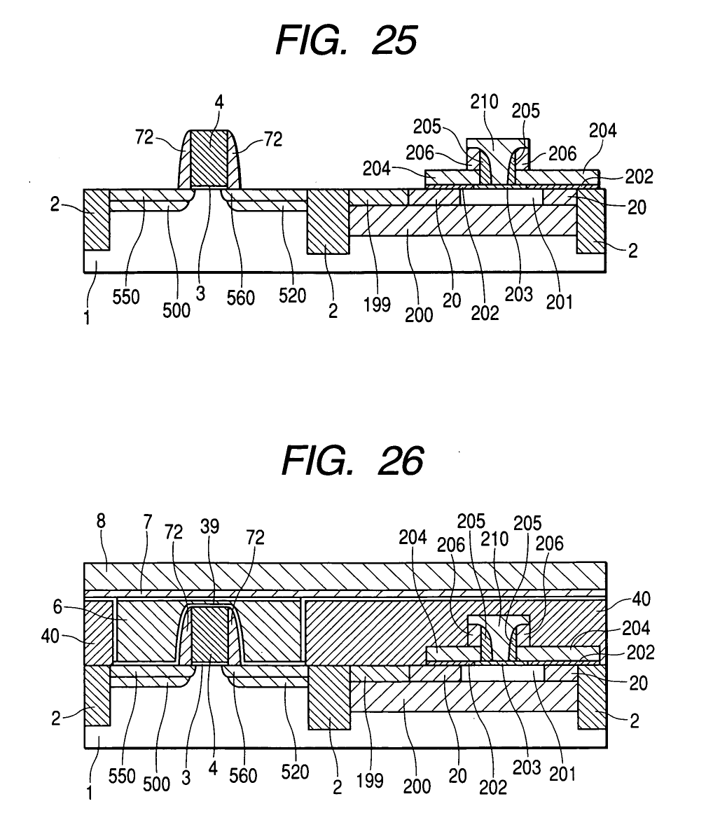

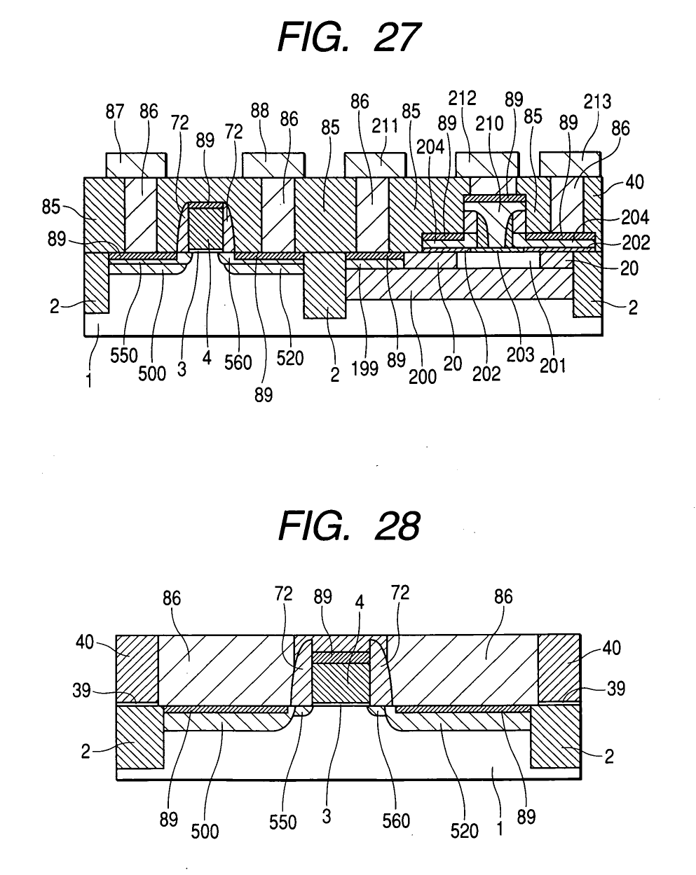

FIG. 25 to FIG. 26 are cross sectional views showing the order of the steps for manufacturing a semiconductor device referred to as a BiCMOS in which a bipolar transistor and an IGFET are hybridized according to a ninth embodiment of the invention, and FIG. 27 is across-sectional view for the completed state thereof. While only an N-P-N type SiGe hetero junction bipolar transistor and an N-type IGFET are shown in the drawing for the sake of simplicity, a complementary IGFET and a bipolar transistor are usually hybridized in one identical substrate and it will be apparent that this embodiment is applicable also to such ordinary semiconductor devices. Further, the bipolar transistor may be constituted also with a usual base junction instead of the Si—Ge hetero junction base as shown in this embodiment. In each of the cross sectional views, the right half shows the bipolar transistor region and the left half shows the N-type IGFET region.

In this embodiment, a super high speed bipolar transistor is at first manufactured to a semiconductor substrate 1 by a known method. Based on the known manufacturing steps for the bipolar transistor, a buried N-conduction type highly doped diffusion layer 200, an inter-device isolation insulation film 2, a collector layer 201 based on epitaxial growing and a base-collector isolation insulation film 20 were formed. In this embodiment, a gate insulation film 3 and a polycrystal Si film constituting a gate electrodes 4 were deposited and a gate electrode protection insulation film (not illustrated) was deposited to the main surface of a semiconductor substrate at a region to form the IGFET and the polycrystal Si film and the gate electrode protection insulation film were selectively removed in the bipolar transistor forming region from this state in accordance with Embodiment 1. Then, after epitaxially growing an Si—Ge mixed crystal film highly doped with boron (B) and Ge to a thickness of about 70 nm on the collector layer 201 also including the portion on the insulation film 20, the Si—Ge mixed crystal film other than the desired region was removed selectively to form a base layer 203. In the epitaxial growing, it was formed with such a concentration gradient that the Ge content was 15% on the collector side and about 5% on the emitter side. A polycrystal region 204 was formed on the insulation film 20. Then, highly B-doped polycrystalline silicon film was deposited and patterned to form a base extension electrode 204.

Then, an insulation film 204 insulatively isolating emitter and base regions was deposited, openings were formed in the regions of the insulation film 206 and the base extension electrode 204 at the region to form the emitter and the insulation film 206 was selectively left on the side wall of the opening. Then, a highly phosphorus-doped polycrystalline silicon film constituting the emitter extension electrode was deposited and patterned to form an emitter extension electrode 210. In the region to form the IGFET, after also removing selectively the polycrystal silicon film forming the insulation film 204 and the emitter extension electrode 210, impurities were added to the gate electrode 4 and then patterned. The patterning may be applied in the step identical with the pattering for the emitter extension electrode. Subsequently, after applying activation for the highly doped impurities added to the gate electrode 4 and the emitter extension electrode 210 by a high temperature short time heat treatment, extremely shallower junction source 55 and drain diffusion layer 56 were formed using the gate electrode as an ion implantation mask, and a gate electrode side wall insulation film 72, and deeper source diffusion layer 50 and drain diffusion layer 52 were formed in accordance with Embodiment 1. The extremely shallower source diffusion layer 55 and drain diffusion layer 56 and deeper source diffusion layer 50 and drain diffusion layer 52 were maintained in the amorphous state (FIG. 25).

From the state shown in FIG. 25, in accordance with Embodiment 1, after depositing a surface protection film 39 comprising an Al oxide film of 10 nm thickness and an Si oxide film 40 of 90 nm thickness for the entire surface at a low temperature of 400° C. or lower, the Si oxide film 40, etc. protruding above the gate electrode 4 were removed selectively by chemical mechanical polishing. Then, in the region to form IGFET, the Si oxide film 40 and the like were opened overstriding the gate electrode 4 by using a mask substantially corresponding to the region including the entire source diffusion layer 50 and drain diffusion layer 52, that is, the region other than the region for the inter-device isolation insulation film 2, to expose the surface of the Al oxide film 39. Successively, a laser energy absorbing film 6 comprising a titanium (Ti) film of 10 nm thickness and a tungsten (W) film of 80 nm thickness was continuously deposited by a sputtering method to fill the inside of the openings. In the state, the laser energy absorbing film 6 comprising the high melting metal film was polished according to a chemical mechanical polishing method used usually in the step of manufacturing connections in the semiconductor device.

Then, an anti-reactive film 7 comprising a TiN film of 10 nm thickness was deposited over the entire planarized surface and, successively, a silicon film of 50 nm thickness was deposited for the entire surface by a chemical vapor phase reaction at a temperature of 400° C. or lower to form an anti-reflective film 8. In this state, laser light irradiation was applied for the entire surface according to Embodiment 1 thereby selectively melting and re-growing in solid phase the extremely shallower source 55 and drain diffusion layer 56 and the deeper source diffusion layer 50 and drain diffusion layer 52 as the amorphous layer.

In this embodiment, while the method of activating heat treatment only of the source and drain diffusion layers in the IGFET region has been described, the activating anneal for the emitter extension electrode 210 in the bipolar transistor can be applied together with the activating anneal for the source and drain diffusion layers. In this case, the Si oxide film 40 or the like was opened and the laser energy absorbing film 6 was selectively filled to the inside of the openings in the emitter region and laser light irradiation may be applied. In this case, the emitter extension electrode 210 is preferably maintained in the amorphous state just before the laser light irradiation (FIG. 26).

From the state shown in FIG. 26, the anti-reflective film 8, the anti-reactive film 7, and the laser energy absorbing film 6 were removed selectively according to Embodiment 1 and the exposed surface protection film 39 was also removed. Then, a metal silicide film 89 was left selectively on the exposed source and drain diffusion layers, the gate electrode, the collector diffusion layer, the base extension electrode and the emitter extension electrode in accordance with the forming steps described in Embodiment 1. Subsequently, an inter-connection insulation film 85 was formed and planarized at the surface by polishing, a contact hole was formed and a connection metal 86 in the contact hole was selectively left to the inside thereof, and electrode and connections including a source electrode 87, a drain electrode 88, a collector electrode 211, an emitter electrode 212 and a base electrode 213 were formed in accordance with a desired circuit structure to form a semiconductor device (FIG. 27).

In the semiconductor device manufactured according to this embodiment, since a high performance bipolar transistor and a high performance IGFET can be manufactured while applying optimal anneal conditions for each of them independently of each other, particularly, in a BICMOS semiconductor device where a bipolar transistor and an IGFET having quite different thermal load conditions are disposed adjacent with each other in one identical semiconductor substrate, a BICMOS transistor of high performance can be compatibilized either for the bipolar transistor and for the IGFET. This can breakthrough the current situation only capable of attaining a combination of an IGFET at a sacrifice of high performance and a bipolar transistor of high performance or a combination of a bipolar transistor at the sacrifice of high performance and an IGFET of high performance in the existent BICMOS. Further, while the semiconductor device in which the IGFET and the bipolar transistor are disposed on one identical semiconductor substrate has been described for this embodiment, it will be apparent that the invention is applicable also to a semiconductor device in which a semiconductor element having structure or performance different from the IGFET of usual structure such as a non-volatile memory transistor or a capacitor element and IGFET of usual structure are disposed in one identical substrate.

<Embodiment 10>

FIG. 28 is a cross sectional view for the completed state of a semiconductor device comprising an IGFET as a main constituent element according to a tenth embodiment of the invention. According to Embodiment 1 described above, an activating anneal was applied to the source and drain diffusion layers. In the semiconductor device according to this embodiment, the activating treatment is not restricted to the laser light irradiation but may also be applied according to any known short time high temperature anneal. After the anneal for the source and drain diffusion layers, an anti-reflective film 8, an anti-reactive film 7 and a laser energy absorbing film 6 were removed selectively and an exposed surface of a protection film 39 was also removed in accordance with Embodiment 1. Then, a metal silicide film 89 was selectively left on the exposed source and drain diffusion layers and the gate electrode according to the forming steps described in Embodiment 1. Subsequently, an anti-reactive metal film comprising TiN was deposited for the entire surface, a connection metal comprising W was deposited for the entire surface, and planarized at the surface by polishing, thereby selectively leaving a connection metal 86 in the contact hole.

In the semiconductor device manufactured according to this embodiment, since connection with the upper connections can be conducted by the metal connection material substantially over the entire region of the source and drain diffusion layers comprising the extremely shallower and deeper diffusion layers, the series resistance can be decreased sufficiently and operation at large current and high speed was enabled. Thus, the surface protection film 39 comprising Al as a main constituent atom extended on the gate electrode and the gate side wall insulation film has a sufficient durability to the patterning for the Si oxide film (inter-connection insulation film) 40, and has a characteristic capable of solving the problem of short circuit with the gate electrode also for the opening overstriding the gate electrode. This is because the contact hole could be formed substantially over the entire region of the source and drain diffusion layers.

<Embodiment 11>

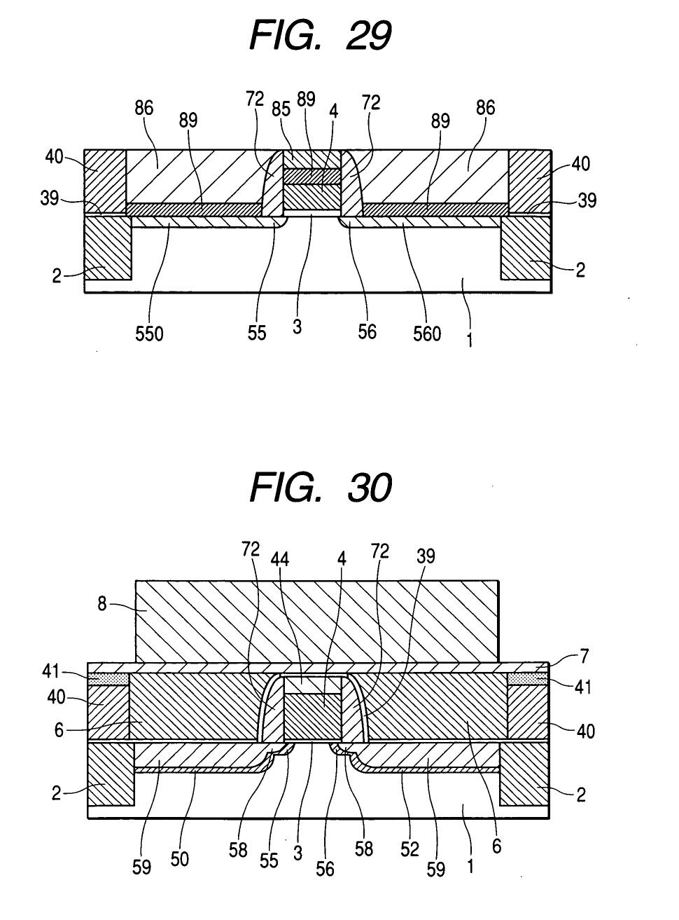

FIG. 29 is a cross sectional view for the completed state of a semiconductor device comprising an IGFET as a main constituent element according to a 11th embodiment of the invention. According to Embodiment 2 described above, a activating heat treatment was applied to the source and drain diffusion layers. In the semiconductor device according to this embodiment, the activating anneal is not restricted to the laser light irradiation but may also be applied according to any known short time high temperature anneal. After the anneal for the source and drain diffusion layers, an anti-reflective film 8, an anti-reactive film 7 and a laser energy absorbing film 6 were removed selectively, and an exposed surface protection film 39 was also removed in accordance with Embodiment 1, semiconductor film was selectively stacked on the exposed source and drain diffusion layers and the metal silicide film 89 was selectively left in accordance with the forming steps of Embodiment 1. Subsequently, an anti-reactive metal film comprising TiN was deposited for the entire surface, a connection metal comprising W was deposited for the entire surface, and planarized at the surface by polishing thereby selectively leaving a connection metal 86 in the contact hole.

In the semiconductor device manufactured according to this embodiment, since connection with the upper connections can be conducted by the metal connection material substantially over the entire region of the source and drain diffusion layers comprising the extremely shallower and deeper diffusion layers and the semiconductor thin film selectively left thereon, the series resistance can be decreased sufficiently and operation at large current and high speed was enabled. This is because the surface protection film 39 comprising Al as a main constituent atom extended on the gate electrode and the gate side wall insulation film has a sufficient durability to the patterning for the Si oxide film (inter-connection insulation film) 40, and has a characteristic capable of solving the problem of short circuit with the gate electrode also for the opening overstriding the gate electrode and thus the contact could be attained substantially over the entire region of the source and drain diffusion layers.

<Embodiment 12>

In Embodiment 1 described above, the anti-reflective film 8 was deposited over the entire surface of the anti-reactive film 7 and the laser irradiation was applied while leaving the entire film surface. This Embodiment 12 shows a case of selectively removing the anti-reflective film 8 except for the desired region. Also the anti-reactive film 7 and the laser energy absorbing film 6 can be selectively removed by using an identical mask with no troubles (FIG. 30).

In the semiconductor integrated circuit manufactured according to this embodiment, device region of a large area and not having the diffusion layer of passive elements constituted on the inter-device isolation insulation film, for example, a capacitance device or a reactance device of a metal/insulation film/metal structure can be previously excluded completely out of the effect of the laser irradiation heating. Thus, the invention is applicable to the laser irradiation activation for the diffusion layer, for example, in a high frequency semiconductor integrated circuit and can provide a semiconductor integrated circuit of further lower electric power consumption and higher frequency operation.

<Embodiment 13>

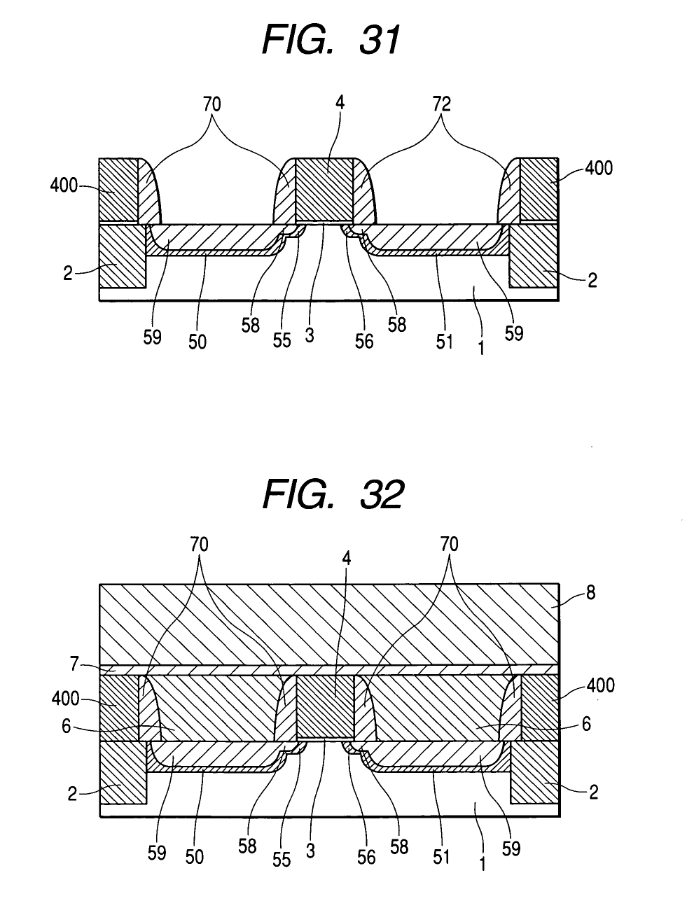

FIG. 31 is a cross sectional view showing the process for the steps of manufacturing an N-conduction type IGFET as a constituent element of a semiconductor integrated circuit according to a 13th embodiment of the invention and FIG. 32 is a cross sectional view of a semiconductor integrated circuit comprising an N-conduction type IGFET as a constituent element showing the state just before applying a laser heat treatment step. For a semiconductor substrate 1 comprising single crystal Si having a face orientation (100), P-conduction type and 20 cm diameter, formation of a inter-device isolation insulation region 2 defining an active region, ion implantation for controlling the threshold voltage and an activating anneal were conducted by a known method of manufacturing semiconductor integrated circuits. Further, a thermal oxide film of 1.8 nm thickness was formed and the surface was nitrided by an NO gas to form a layered nitride film of 0.2 nm as a gate insulation film 3. The nitride film has a higher specific dielectric constant than that of the Si thermal oxide film and optical film thickness electrically equivalent with the Si thermal oxide film corresponds to about 2 times the thickness. Successively, a polycrystalline Si film and a silicon oxide film were deposited each at 50 nm and 10 nm thickness on the gate insulation film 3 continuously by a chemical vapor phase deposition method and patterned to form a gate electrode 4, and a dummy gate electrode 400 and a gate protection film (not illustrated) on the inter-device isolation insulation film by a known manufacturing method for the IGFET. Impurities were doped at high concentration to the polycrystal Si film by ion implantation of P. The width of the gate electrode, that is, the minimum value of the gate length was 30 nm, the minimum inter-electrode distance was 90 nm, and the height of the gate electrode including the gate protection insulation film 45 was 60 nm. After forming the gate electrode 4, As ion implantation was conducted using the electrode as an implantation inhibitive mask under the condition at an acceleration energy of 3 keV and an implantation dose of 5×10¹⁵/cm² to form an extremely shallower source diffusion layer 55 and an extremely shallower drain diffusion layer 56 including an amorphous layer 58. The ion implantation may be conducted with no problems also by leaving an insulation film selectively on the gate electrode side wall and using the insulation film as an implantation inhibitive mask. By the method, the distance between the end of the gate electrode and the end of the highly doped source and drain diffusion layers can be changed to improve the punch through withstanding voltage as well. In this state, after depositing a silicon oxide film at a low temperature of 350° C. over the entire surface to a thickness of 30 nm, anisotropic etching was applied to selectively leave the same on the side wall for the gate electrode 4 and the dummy electrode 400 to form a gate side wall insulation film 70. Successively, As ion implantation was conducted by using the gate electrode 4 and gate side wall insulation film 70 as an implantation inhibitive mask under the condition at an acceleration energy of 40 keV and an implantation dose of 4×10¹⁵/cm² to form a deeper source diffusion layer 50 and a deeper drain diffusion layer 51 including an amorphous layer 59 (FIG. 31).

From the state shown in FIG. 31, a surface protection film, and a laser energy absorbing film 6 comprising a Ti film and a W film were deposited continuously in accordance with Embodiment 1. In this Embodiment 1, a silicon nitride film of 5 nm thickness was used as the surface protection film, and the thickness for the Ti film was 10 nm and that for the W film was 50 nm. Each film deposition was conducted at a low temperature of 400° C. or lower. Successively, the laser energy absorbing film 6 comprising the metal film with high melting point was polished based on the chemical mechanical polishing method according to Embodiment 1. The end point for polishing was controlled and decided by means of polishing time. By the selective polishing, the metal film with high melting point above the underlying protruding portion was completely removed and the laser energy absorbing film 6 comprising the high melting metal film was selectively left only for the underlying concave region. Then, an anti-reactive film 7 comprising a TiN film was deposited to a thickness of 10 nm or less over the entire planarized surface and, successively, an amorphous silicon film of 200 nm thickness was deposited over the entire surface by chemical vapor phase reaction at a temperature of 400° C. or lower to form an anti-reflective film 8 (FIG. 32).

From the state shown in FIG. 32, YAG laser using semiconductor laser excitation was irradiated to melt the amorphous layers 58 and 59 in the highly doped extremely shallower source and drain regions 55 and 56 and deeper source and drain diffusion layers 50 and 51 simultaneously by extremely short time heating to the laser energy absorbing film 6 and then they were grown in solid phase. The irradiation wavelength was 1064 nm, the half value width of the irradiation pulse was 90 ns and the irradiation energy density was 650 mJ/cm². The irradiation area was 5×5 mm² and it was conducted such that regions at the energy density of 95% or less of the maximum level overlapped to each other in the entire surface irradiation. By the laser light irradiation, the amorphous layer 59 in the underlying highly doped source and drain diffusion layers 50 and 51 were melted instantaneously and then recyrstallized. When the impurity distribution in the direction of the depth in the semiconductor substrate was measured by secondary ion mass spectroscopy regarding a separately prepared specimen under the same conditions as those for the ion implantation to the extremely shallower source and drain diffusion layers, it was found that the As impurities were re-distributed in the course of melting so as to form a uniform box shaped highly doped concentration of about 5×10²¹/cm³ in a molten region and the thickness was about 15 nm. The maximum doping gradient in the impurity distribution was 2.3 nm/decade and a further abrupt gradient was attained than the maximum doping gradient of 3.5 nm/decade just after the ion implantation before the activation. For the impurity distribution in the fine region just below the end of the gate electrode and the region of the source and drain diffusion layer 51 to make the inter-gate electrode size minimum, it was confirmed to be a uniform box shaped highly doped distribution also in the observation for the highly doped impurity distribution by using an energy dispersive spectroscopy by a cross sectional transmission electron microscope for a separately prepared specimen. Further, failure of loss of pattern caused by evaporation of the gate electrode, etc. was not present at all. This is considered to be attributable to that heating of the gate electrode by the laser irradiation was suppressed sufficiently by the constitution in which the laser energy absorbing film is not disposed on the gate electrode 4 and the gate side wall is isolated by the thick insulation film of 30 nm thickness from the laser energy absorbing film. After the simultaneous activation for the extremely shallower and deeper source and drain diffusion layers by laser light irradiation, the anti-reflective film 8 was removed by dry etching and the anti-reactive film 7 and the laser energy absorbing film 6 were removed by an etching solution selectively in accordance with Embodiment 1 to expose the surface of the source and drain diffusion layers 50 and 51. In this state, in accordance with a method of manufacturing a semiconductor integrated circuit comprising an IGFET as a main constituent element, a Co silicide film 89 was formed selectively on the gate electrode 4 and the source and drain diffusion layers 50 and 51, an inter-connection insulation film 85 was deposited, planarized by polishing and opened at desired regions, a connection metal was buried to the openings and planarized, and a wiring step including a source electrode 87 and a drain electrode 88 was conducted to manufacture a semiconductor integrated circuit (not illustrated).

By way of the manufacturing steps described above, all the regions over the amorphous layer can be activated simultaneously by melting and re-solidifying all the regions over the amorphous layer as the region intended for melting including the highly doped source and drain diffusion layers 55 and 56 having the extremely shallower junction and the highly doped source and drain diffusion layers 50 and 51 having deeper junction except for the portion just below the gate electrode. In this case, the laser energy absorbing film 6 could be designed uniformly irrespective of the underlying shape, it was not left on the gate electrode not intended for melting and the heating of the gate electrode could be suppressed both from above and from the lateral side of the gate. Further, the thickness of the anti-reflective film 8 was 200 nm on the region intended for melting and it could be set constant for all the regions intended for activation to the condition of maximizing the absorptivity to the YAG laser at 1064 nm (reflectivity: about 0%) not depending on the underlying shape. In the N-channel IGFET of 30 nm gate length manufactured by the method described above, the extremely shallower source diffusion layer 50 and the extremely shallower drain diffusion layer 52 had a junction depth of about 10 nm and a sheet resistance of 150 Ω/□, and extremely shallower junction and lower resistance could be obtained compared with the value for the junction depth of 30 nm and the sheet resistance of 450 Ω/□ in a case of the existent short time high temperature heat treatment of conducting the activating treatment at 1000° C. for 1 sec. It was also confirmed that the resistance value of the extremely shallower highly doped diffusion layer 51 constituted in a narrow region with the gate electrode distance of 90 nm corresponded to the sheet resistance of 150 Ω/□ in view of the evaluation for the current/voltage characteristics of IGFET. Further, it was also confirmed that the resistance value for the extremely shallower highly doped diffusion layer 51 between the gate electrodes did not depend on the inter-electrode distance, and presence of crystal defects such as twins was not observed at all as apparent from the result of the cross sectional electron microscopic observation and complete crystallization was attained not depending on the inter-gate electrode distance.

In the semiconductor device, micro-refinement reached its limit in view of the shallowing of the junction and the lowering of the resistance for the solid phase-grown source and drain diffusion layers based on the existent high temperature short time heat treatment. According to the present invention, by applying laser irradiation to the amorphous layer for the source and drain formed by ion implantation and selectively growing the amorphous layer in liquid phase, source and drain diffusion layers of extremely shallower junction and lower resistance can be obtained by a further abrupt highly doped box shaped distribution than the impurity distribution upon implantation and outstanding improvement for the solid solubility.

According to the invention, since the laser annealed region can be selected in a self-alignment manner relative to the gate electrode and it does not accompany heating of the gate electrode itself, this does not cause failure such as configurational deterioration of the gate electrode or leak diffusion of impurities added to the gate electrode by way of the extremely thin gate insulation film and, further, deterioration of the gate insulation film. Accordingly, further micro-refinement and higher integration degree are possible for semiconductor devices and it can provide the effect of enabling further reduced power consumption and higher speed operation of semiconductor devices.

Further, according to the present invention, in a so-called BICMOS in which a bipolar transistor and an IGFET are hybridized in one identical semiconductor substrate, since optimum heat treatment conditions for the manufacture of the high performance bipolar transistor and optimum heat treatment conditions for the manufacture of the high performance IGFET can be selected independently of each other and applied in one identical semiconductor substrate, this can provide an advantageous effect capable of manufacturing a high performance bipolar transistor and a high performance IGFET in one identical semiconductor substrate.

1. A semiconductor device including a gate portion comprising a semiconductor film disposed at a predetermined region on the surface of a semiconductor substrate, and
source and drain regions comprising an impurity introduced layer formed by introducing impurities selectively to the inside of the semiconductor substrate, wherein
the gate portion and a region just below the gate portion are not melted by the irradiation of a laser light and the impurity introduced layer comprises a melted and re-solidified layer.

2. A semiconductor device according to claim 1, wherein the semiconductor substrate is mounted on an insulation film.

3. A semiconductor device according to claim 1, wherein an insulated gate field effect transistor and a bipolar transistor are formed on one identical semiconductor substrate.

4. A semiconductor device according to claim 1, wherein at least one kind of a semiconductor film, a SILICON silicide film or a metal film is present between the source and drain regions and electrodes for electrically connecting the regions.

5. A semiconductor device including a gate portion comprising a semiconductor film disposed at a predetermined region on the surface of a semiconductor substrate, and
source and drain regions comprising an impurity introduced layer formed by introducing impurities selectively to the inside of the semiconductor substrate by using the semiconductor film as a mask, wherein
the impurity introduced layer comprises an impurity layer having a box shaped highly doped impurity distribution on at least one cross section perpendicular to the main surface of the semiconductor substrate.

6. A semiconductor device according to claim 5, wherein the semiconductor substrate is mounted on an insulation film.

7. A semiconductor device according to claim 5, wherein an insulated gate field effect transistor and a bipolar transistor are formed on one identical semiconductor substrate.

8. A semiconductor device according to claim 5, wherein at least one kind of a semiconductor film, a SILICON silicide film or a metal film is present between the source and drain regions and electrodes for electrically connecting the regions.

9. A semiconductor device including:
a first region having a first conduction type formed in a semiconductor substrate;
a second region having a second conduction type disposed adjacent with the first region;
a gate portion comprising a semiconductor film disposed to a predetermined region on the first region;
source and drain regions comprising a first impurity introduced layer formed by introducing impurities having a second conduction type selectively to the first region by using the semiconductor film as a mask;
a gate portion comprising a semiconductor film disposed to a predetermined region on the second region; and
source and drain regions comprising a second impurity introduced layer formed by introducing impurities having a first conduction type selectively to the second region by using the semiconductor film as a mask, wherein
the first and the second impurity introduced layers each comprises an impurity layer having a box shaped highly doped impurity distribution on at least one cross section perpendicular to the main surface of the semiconductor substrate.

10. A semiconductor device according to claim 9, wherein the semiconductor substrate is mounted on an insulation film.

11. A semiconductor device according to claim 9, wherein an insulated gate field effect transistor and a bipolar transistor are formed on one identical semiconductor substrate.

12. A semiconductor device according to claim 9, wherein at least one kind of a semiconductor film, a SILICON silicide film or a metal film is present between the source and drain regions and electrodes for electrically connecting the regions.

13.-48. (Cancelled)
